(19) United States
(12) Patent Application Publication
(10) Pub. No.: US 2025/0200484 A1
(43) Pub. Date: Jun. 19, 2025

(54) SYSTEMS AND METHODS FOR HYBRID AI-DRIVEN PRESCRIPTIVE VIRTUAL OPERATIONAL ASSISTANCE

(71) Applicant: Vectrona, LLC, Virginia Beach, VA (US)

(72) Inventors: Joseph Edward GELARDI, Virginia Beach, VA (US); Henry Caleb HOUGH, Virginia Beach, VA (US); John Patrick FOUTS, Virginia Beach, VA (US); Erin James PICKEL, Virginia Beach, VA (US)

(73) Assignee: Vectrona, LLC, Virginia Beach, VA (US)

(21) Appl. No.: 18/983,310

(22) Filed: Dec. 16, 2024

Related U.S. Application Data
(60) Provisional application No. 63/610,990, filed on Dec. 15, 2023.

(51) Int. Cl. G06Q 10/0639; G06Q 50/26

(52) U.S. Cl. CPC G06Q 10/0639; G06Q 50/26

(57) ABSTRACT

A method, computer program product, and computer system for receiving, by a computing device, input data from a user participating in a live simulation scenario. Input data from the live operation may be received. The input data from the user participating in the live operation and the input data from the live operation may be analyzed. Feedback may be provided to the user participating in the live operation based upon, at least in part, analyzing the input data from the user participating in the live operation and the input data from the live operation.

### RELATED CASES

This application claims the benefit of U.S. Provisional Application No. 63/610,990, filed on 15 Dec. 2023, the contents of which are all incorporated by reference.

### GOVERNMENT LICENSE RIGHTS

This invention was made with government support under FA864921P0935 awarded by the US Air Force. The government has certain rights in the invention.

### BACKGROUND

Generally speaking, Command and Control (C2) is the exercise of authority and direction by a properly designated individual over assigned and attached forces, assets, or personnel in the accomplishment of a mission/goal. It typically involves a range of operational processes, interconnected systems, and organizational structures increasingly augmented by advanced AI methodologies. These methodologies, including predictive and prescriptive analytics, enhance decision-making, resource optimization, and operational adaptability across diverse applications, including commercial operations, emergency management, and military missions. Modern C2 environments are increasingly complex, requiring seamless integration of advanced technologies to facilitate timely and informed decisions and ensuring that the necessary resources (e.g., troops, vehicles, equipment, etc.) are available and effectively employed to achieve mission objectives. C2 may cover the spectrum of, e.g., commercial, emergency management, and military applications for the safe and effective conduct of operations in diverse environments and conditions.

### SUMMARY

In one example implementation, a method, performed by one or more computing devices, may include but is not limited to receiving, by a computing device, input data from a user participating in a live operation. Input data from the live operation may be received. The input data from the user participating in the live operation and the input data from the live operation may be analyzed. Feedback may be provided to the user participating in the live operation based upon, at least in part, analyzing the input data from the user participating in the live operation and the input data from the live operation.

One or more of the following example features may be included. The input data from the user participating in the live operation may include at least one of user biometrics and user performance data, and wherein the input data from the live operation includes live state data. Performance of the user in the live operation may be predicted to generate a predicted performance of the user. Predicting performance of the user in the live operation to generate the predicted performance of the user may include processing, using a trained predictive model, at least one of input data from the user participating in a past simulation scenario, input data from the user participating in a past live operation, the input data from the user participating in the live operation, and the input data from the live operation processed using feature engineering data. Providing feedback to the user participating in the live operation may include triggering an intervention event in the live operation based upon, at least in part the input data from the user participating in the live operation and the input data from the live operation. One of a predicted performance of the user, the input data from the user participating in the live operation, and the input data from the live operation may be matched to a rule of a plurality of rules. Triggering the intervention event may include providing at least one of a visual cue, an audio cue, a virtual cue, and a virtual intervention.

In another example implementation, a computing system may include one or more processors and one or more memories configured to perform operations that may include but are not limited to receiving, by a computing device, input data from a user participating in a live operation. Input data from the live operation may be received. The input data from the user participating in the live operation and the input data from the live operation may be analyzed. Feedback may be provided to the user participating in the live operation based upon, at least in part, analyzing the input data from the user participating in the live operation and the input data from the live operation.

One or more of the following example features may be included. The input data from the user participating in the live operation may include at least one of user biometrics and user performance data, and wherein the input data from the live operation includes live state data. Performance of the user in the live operation may be predicted to generate a predicted performance of the user. Predicting performance of the user in the live operation to generate the predicted performance of the user may include processing, using a trained predictive model, at least one of input data from the user participating in a past simulation scenario, input data from the user participating in a past live operation, the input data from the user participating in the live operation, and the input data from the live operation processed using feature engineering data. Providing feedback to the user participating in the live operation may include triggering an intervention event in the live operation based upon, at least in part the input data from the user participating in the live operation and the input data from the live operation. One of a predicted performance of the user, the input data from the user participating in the live operation, and the input data from the live operation may be matched to a rule of a plurality of rules. Triggering the intervention event may include providing at least one of a visual cue, an audio cue, a virtual cue, and a virtual intervention.

In another example implementation, a computer program product may reside on a computer readable storage medium having a plurality of instructions stored thereon which, when executed across one or more processors, may cause at least a portion of the one or more processors to perform operations that may include but are not limited to receiving, by a computing device, input data from a user participating in a live operation. Input data from the live operation may be received. The input data from the user participating in the live operation and the input data from the live operation may be analyzed. Feedback may be provided to the user participating in the live operation based upon, at least in part, analyzing the input data from the user participating in the live operation and the input data from the live operation.

One or more of the following example features may be included. The input data from the user participating in the live operation may include at least one of user biometrics and user performance data, and wherein the input data from the live operation includes live state data. Performance of the user in the live operation may be predicted to generate a predicted performance of the user. Predicting performance of the user in the live operation to generate the predicted performance of the user may include processing, using a trained predictive model, at least one of input data from the user participating in a past simulation scenario, input data from the user participating in a past live operation, the input data from the user participating in the live operation, and the input data from the live operation processed using feature engineering data. Providing feedback to the user participating in the live operation may include triggering an intervention event in the live operation based upon, at least in part the input data from the user participating in the live operation and the input data from the live operation. One of a predicted performance of the user, the input data from the user participating in the live operation, and the input data from the live operation may be matched to a rule of a plurality of rules. Triggering the intervention event may include providing at least one of a visual cue, an audio cue, a virtual cue, and a virtual intervention.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF DRAWINGS

FIG. 1 is an example diagrammatic view of a tutor process coupled to an example distributed computing network according to one or more example implementations of the disclosure;

FIG. 2 is an example diagrammatic view of a client electronic device of FIG. 1 according to one or more example implementations of the disclosure;

FIG. 3 is an example flowchart of a tutor process according to one or more example implementations of the disclosure;

FIG. 4 is an example diagrammatic view of a simulation system that may be use by a tutor process according to one or more example implementations of the disclosure;

FIG. 5 is an example diagrammatic view of RAI components according to one or more example implementations of the disclosure;

FIG. 6 is an example diagrammatic view of trigger options of a simulation system that may be used by a tutor process according to one or more example implementations of the disclosure;

FIG. 7 is an example flowchart of a tutor process according to one or more example implementations of the disclosure;

FIG. 8 is an example flowchart of a tutor process according to one or more example implementations of the disclosure;

FIG. 9 is an example flowchart of a tutor process according to one or more example implementations of the disclosure;

FIG. 10 is an example flowchart of a tutor process according to one or more example implementations of the disclosure;

FIG. 11 is an example flowchart of a tutor process according to one or more example implementations of the disclosure; and

FIG. 12 is an example diagrammatic view of a real-world system that may be used by a tutor process according to one or more example implementations of the disclosure.

Like reference symbols in the various drawings may indicate like elements.

### DESCRIPTION

### System Overview

In some implementations, the present disclosure may be embodied as a method, system, or computer program product. Accordingly, in some implementations, the present disclosure may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, in some implementations, the present disclosure may take the form of a computer program product on a computer-usable storage medium having computer-usable program code embodied in the medium. These implementations may include advanced AI-enabled circuits, modules, or systems capable of dynamically adapting operations through predictive and prescriptive analytics, enhancing efficiency and decision-making across a wide range of applications.

Software may include artificial intelligence systems, which may include machine learning or other computational intelligence. For example, artificial intelligence (AI) may include one or more models used for one or more problem domains. When presented with many data features, identification of a subset of features that are relevant to a problem domain may improve prediction accuracy, reduce storage space, and increase processing speed. This identification may be referred to as feature engineering. Feature engineering may be performed by users or may only be guided by users. In various implementations, a machine learning system may computationally identify relevant features, such as by performing singular value decomposition on the contributions of different features to outputs.

In some implementations, the various computing devices may include, integrate with, link to, exchange data with, be governed by, take inputs from, and/or provide outputs to one or more AI systems, which may include models, rule-based systems, expert systems, neural networks, deep learning systems, supervised learning systems, robotic process automation systems, natural language processing systems, intelligent agent systems, self-optimizing and self-organizing systems, transformer-based architectures, and others. Except where context specifically indicates otherwise, references to AI, or to one or more examples of AI, should be understood to encompass one or more of these various alternative methods and systems; for example, without limitation, an AI system described for enabling any of a wide variety of functions, capabilities and solutions described herein (such as optimization, autonomous operation, prediction, control, orchestration, or the like) should be understood to be capable of implementation by operation on a model or rule set; by training on a training data set of human tag, labels, or the like; by training on a training data set of human interactions (e.g., human interactions with software interfaces or hardware systems); by training on a training data set of outcomes; by training on an AI-generated training data set (e.g., where a full training data set is generated by AI from a seed training data set); by supervised learning; by semi-supervised learning; by deep learning; or the like. For any given function or capability that is described herein, neural networks of various types may be used, including any of the types described herein, and in embodiments a hybrid set of neural networks may be selected such that within the set a neural network type that is more favorable for performing each element of a multi-function or multi-capability system or method is implemented. Advanced AI tools such as large language models and hybrid neural networks enable nuanced decision-making, prescriptive scenario adjustments, and intelligent automation across training and operational contexts. As one example among many, a deep learning, or black box, system may use a gated recurrent neural network for a function like language translation for an intelligent agent, where the underlying mechanisms of AI operation need not be understood as long as outcomes are favorably perceived by users, while a more transparent model or system and a simpler neural network may be used for a system for automated governance, where a greater understanding of how inputs are translated to outputs may be needed to comply with regulations or policies.

Examples of the models (e.g., AI-based models) include recurrent neural networks (RNNs) such as long short-term memory (LSTM), deep learning models such as transformers, decision trees, support-vector machines, genetic algorithms, Bayesian networks, and regression analysis. Examples of systems based on a transformer model include bidirectional encoder representations from transformers (BERT) and generative pre-trained transformers (GPT). Training a machine-learning model (or other type of AI-based learning models) may include supervised learning (for example, based on labelled input data), unsupervised learning, and reinforcement learning. In various embodiments, a machine-learning model may be pre-trained by their operator or by a third party. Problem domains include nearly any situation where structured data can be collected, and includes natural language processing (NLP), computer vision (CV), classification, image recognition, etc. Some or all of the software may run in a virtual environment rather than directly on hardware. The virtual environment may include a hypervisor, emulator, sandbox, container engine, etc. The software may be built as a virtual machine, a container, etc. Virtualized resources may be controlled using, for example, a DOCKER container platform, a pivotal cloud foundry (PCF) platform, etc. Some or all of the software may be logically partitioned into microservices. Each microservice offers a reduced subset of functionality. In various embodiments, each microservice may be scaled independently depending on load, either by devoting more resources to the microservice or by instantiating more instances of the microservice. In various embodiments, functionality offered by one or more microservices may be combined with each other and/or with other software not adhering to a microservices model.

In some implementations, as noted above, AI-based learning models may include at least one of a transformer model, a convolutional neural network, a deep learning model trained on a set of outcomes of the value chain network entity, a supervised model, a semi-supervised model, an unsupervised model, or a reinforcement model, and the training data set for the AI-based learning models may include one or a set of objects or events that are labeled to classify the set of objects or events according to a classification taxonomy. Other examples of AI-based learning models (e.g., machine learning models) may include neural networks in general (e.g., deep neural networks, convolution neural networks, and many others), regression based models, decision trees, hidden forests, Hidden Markov models, Bayesian models, genetic algorithms, large language models (LLMs), and other transformer-based architectures. In some implementations, the present disclosure may include combinations where an expert system uses one neural network for classifying an item and a different (or the same) neural network for predicting a state of the item, or employs hybrid approaches that integrate symbolic reasoning, rule-based engines, and AI models of various types to achieve desired outcomes.

In some implementations, any suitable computer usable or computer readable medium (or media) may be utilized. The computer readable medium may be a computer readable signal medium or a computer readable storage medium. The computer-usable, or computer-readable, storage medium (including a storage device associated with a computing device or client electronic device) may be, for example, but is not limited to, an electronic, magnetic, optical, electromagnetic, infrared, or semiconductor system, apparatus, device, or any suitable combination of the foregoing. More specific examples (a non-exhaustive list) of the computer-readable medium or storage device may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, solid state drives (SSDs), a digital versatile disk (DVD), a Blu-ray disc, and an Ultra HD Blu-ray disc, a static random access memory (SRAM), dynamic RAM (DRAM), synchronous DRAM (SDRAM), synchronous graphics RAM (SGRAM), and video RAM (VRAM), analog magnetic tape, digital magnetic tape, rotating hard disk drive (HDDs), a memory stick, a floppy disk, a mechanically encoded device such as punch-cards or raised structures in a groove having instructions recorded thereon, a media such as those supporting the internet or an intranet, or a magnetic storage device. Note that the computer-usable or computer-readable medium could even be a suitable medium upon which the program is stored, scanned, compiled, interpreted, or otherwise processed in a suitable manner, if necessary, and then stored in a computer memory. In the context of the present disclosure, a computer-usable or computer-readable, storage medium may be any tangible medium that can contain or store a program for use by or in connection with the instruction execution system, apparatus, or device.

Examples of storage implemented by the storage hardware include a distributed ledger, such as a permissioned or permissionless blockchain. Entities recording transactions, such as in a blockchain, may reach consensus using an algorithm such as proof-of-stake, proof-of-work, and proof-of-storage. Elements of the present disclosure may be represented by or encoded as non-fungible tokens (NFTs). Ownership rights related to the non-fungible tokens may be recorded in or referenced by a distributed ledger. Transactions initiated by or relevant to the present disclosure may use one or both of fiat currency and cryptocurrencies, examples of which include bitcoin and ether.

In some implementations, a computer readable signal medium may include a propagated data signal with computer readable program code embodied therein, for example, in baseband or as part of a carrier wave. In some implementations, such a propagated signal may take any of a variety of forms, including, but not limited to, electromagnetic, optical, or any suitable combination thereof. In some implementations, the computer readable program code may be transmitted using any appropriate medium, including but not limited to the internet, wireline, optical fiber cable, RF, etc. In some implementations, a computer readable signal medium may be any computer readable medium that is not a computer readable storage medium and that can communicate, propagate, or transport a program for use by or in connection with an instruction execution system, apparatus, or device.

In some implementations, computer program code for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java®, Smalltalk, C++ or the like. Java® and all Java-based trademarks and logos are trademarks or registered trademarks of Oracle and/or its affiliates. However, the computer program code for carrying out operations of the present disclosure may also be written in conventional procedural programming languages, such as the “C” programming language, PASCAL, or similar programming languages, as well as in scripting languages such as JavaScript, PERL, or Python. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a network, such as a cellular network, local area network (LAN), a wide area network (WAN), a body area network BAN), a personal area network (PAN), a metropolitan area network (MAN), etc., or the connection may be made to an external computer (for example, through the internet using an Internet Service Provider). The networks may include one or more of point-to-point and mesh technologies. Data transmitted or received by the networking components may traverse the same or different networks. Networks may be connected to each other over a WAN or point-to-point leased lines using technologies such as Multiprotocol Label Switching (MPLS) and virtual private networks (VPNs), etc. In some implementations, electronic circuitry including, for example, programmable logic circuitry, an application specific integrated circuit (ASIC), gate arrays such as field-programmable gate arrays (FPGAs) or other hardware accelerators, micro-controller units (MCUs), or programmable logic arrays (PLAs), integrated circuits (ICs), digital circuit elements, analog circuit elements, combinational logic circuits, digital signal processors (DSPs), complex programmable logic devices (CPLDs), etc. may execute the computer readable program instructions/code by utilizing state information of the computer readable program instructions to personalize the electronic circuitry, in order to perform aspects of the present disclosure. Multiple components of the hardware may be integrated, such as on a single die, in a single package, or on a single printed circuit board or logic board. For example, multiple components of the hardware may be implemented as a system-on-chip. A component, or a set of integrated components, may be referred to as a chip, chipset, chiplet, or chip stack. Examples of a system-on-chip include a radio frequency (RF) system-on-chip, an artificial intelligence (AI) system-on-chip, a video processing system-on-chip, an organ-on-chip, a quantum algorithm system-on-chip, etc.

Examples of processing hardware may include, e.g., a central processing unit (CPU), a graphics processing unit (GPU), an approximate computing processor, a quantum computing processor, a parallel computing processor, a neural network processor, a signal processor, a digital processor, an analog processor, a data processor, an embedded processor, a microprocessor, and a co-processor. The co-processor may provide additional processing functions and/or optimizations, such as for speed or power consumption. Examples of a co-processor include a math co-processor, a graphics co-processor, a communication co-processor, a video co-processor, and an artificial intelligence (AI) co-processor.

In some implementations, the flowchart and block diagrams in the figures illustrate the architecture, functionality, and operation of possible implementations of apparatus (systems), methods and computer program products according to various implementations of the present disclosure. Each block in the flowchart and/or block diagrams, and combinations of blocks in the flowchart and/or block diagrams, may represent a module, segment, or portion of code, which comprises one or more executable computer program instructions for implementing the specified logical function(s)/act(s). These functions or operations may leverage AI-driven modules, including predictive analytics for insight generation and prescriptive analytics for scenario optimization, ensuring systems dynamically adapt to achieve targeted outcomes. These computer program instructions may be provided to a processor of a general purpose computer, special purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) may occur out of the order noted in the figures (or combined or omitted). For example, two blocks shown in succession may, in fact, be executed substantially concurrently, or the blocks may sometimes be executed in the reverse order, depending upon the functionality involved.

In some implementations, these computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

In some implementations, the computer program instructions may also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

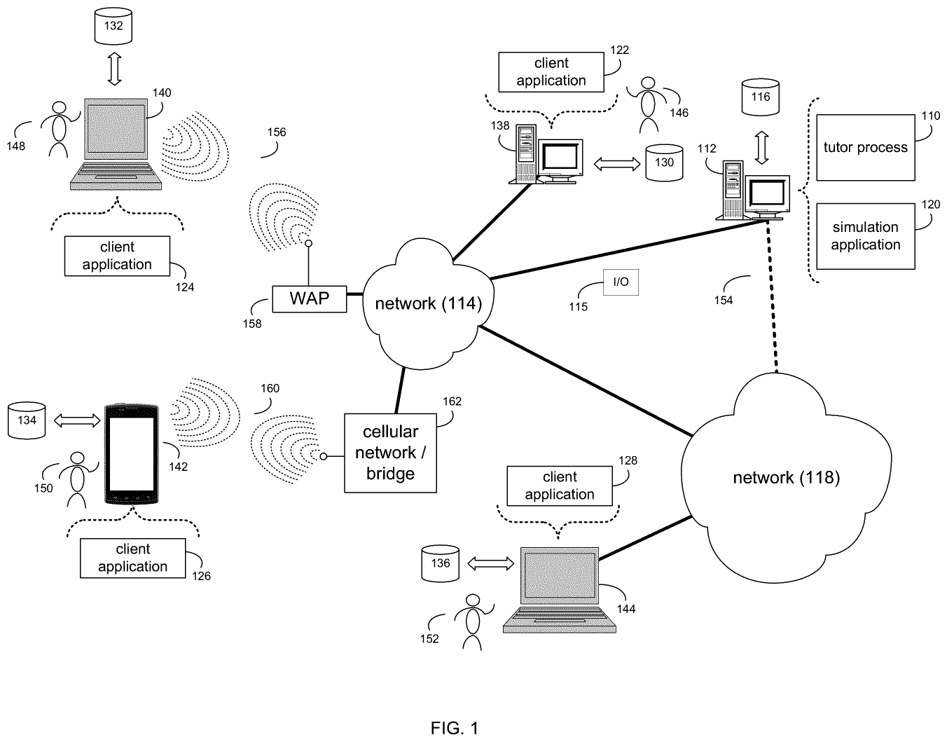

Referring now to the example implementation of FIG. 1, there is shown tutor process 110 that may reside on and may be executed by a computer (e.g., computer 112), which may be connected to a network (e.g., network 114) (e.g., the internet or a local area network). Examples of computer 112 (and/or one or more of the client electronic devices noted below) may include, but are not limited to, a storage system (e.g., a Network Attached Storage (NAS) system, a Storage Area Network (SAN)), a personal computer(s), a laptop computer(s), mobile computing device(s), a server computer, a series of server computers, a mainframe computer(s), or a computing cloud(s). A SAN may include one or more of the client electronic devices, including a RAID device and a NAS system. In some implementations, each of the aforementioned may be generally described as a computing device. In certain implementations, a computing device may be a physical or virtual device. In many implementations, a computing device may be any device capable of performing operations, such as a dedicated processor, a portion of a processor, a virtual processor, a portion of a virtual processor, portion of a virtual device, or a virtual device. In some implementations, a processor may be a physical processor or a virtual processor. In some implementations, a virtual processor may correspond to one or more parts of one or more physical processors. In some implementations, the instructions/logic may be distributed and executed across one or more processors, virtual or physical, to execute the instructions/logic. Computer 112 may execute an operating system, for example, but not limited to, Microsoft® Windows®; Mac® OS X®; Red Hat® Linux®, Windows® Mobile, Chrome OS, Blackberry OS, Fire OS, or a custom operating system. (Microsoft and Windows are registered trademarks of Microsoft Corporation in the United States, other countries or both; Mac and OS X are registered trademarks of Apple Inc. in the United States, other countries or both; Red Hat is a registered trademark of Red Hat Corporation in the United States, other countries or both; and Linux is a registered trademark of Linus Torvalds in the United States, other countries or both).

In some implementations, the instruction sets and subroutines of tutor process 110, which may be stored on storage device, such as storage device 116, coupled to computer 112, may be executed by one or more processors and one or more memory architectures included within computer 112. In some implementations, storage device 116 may include but is not limited to: a hard disk drive; all forms of flash memory storage devices; a tape drive; an optical drive; a RAID array (or other array); a random access memory (RAM); a read-only memory (ROM); or combination thereof. In some implementations, storage device 116 may be organized as an extent, an extent pool, a RAID extent (e.g., an example 4D+1P R5, where the RAID extent may include, e.g., five storage device extents that may be allocated from, e.g., five different storage devices), a mapped RAID (e.g., a collection of RAID extents), or combination thereof.

In some implementations, network 114 may be connected to one or more secondary networks (e.g., network 118), examples of which may include but are not limited to: a local area network; a wide area network or other telecommunications network facility; or an intranet, for example. The phrase “telecommunications network facility,” as used herein, may refer to a facility configured to transmit, and/or receive transmissions to/from one or more mobile client electronic devices (e.g., cellphones, etc.) as well as many others.

In some implementations, computer 112 may include a data store, such as a database (e.g., relational database, object-oriented database, triplestore database, etc.), a data store, a data lake, a column store, and/or a data warehouse, and may be located within any suitable memory location, such as storage device 116 coupled to computer 112. In some implementations, data, metadata, information, etc. described throughout the present disclosure may be stored in the data store. In some implementations, computer 112 may utilize any known database management system such as, but not limited to, DB2, in order to provide multi-user access to one or more databases, such as the above noted relational database. In some implementations, the data store may also be a custom database, such as, for example, a flat file database or an XML database. In some implementations, any other form(s) of a data storage structure and/or organization may also be used. In some implementations, tutor process 110 may be a component of the data store, a standalone application that interfaces with the above noted data store and/or an applet/application that is accessed via client applications 122, 124, 126, 128. In some implementations, the above noted data store may be, in whole or in part, distributed in a cloud computing topology. In this way, computer 112 and storage device 116 may refer to multiple devices, which may also be distributed throughout the network.

In some implementations, computer 112 may execute a simulation application (e.g., simulation application 120), examples of which may include, but are not limited to, e.g., an automatic speech recognition (ASR) application, examples of which may include, but are not limited to, e.g., an ASR application (e.g., modeling, transcription, etc.), a natural language understanding (NLU) application (e.g., machine learning, intent discovery, etc.), a text to speech (TTS) application (e.g., context awareness, learning, etc.), a speech signal enhancement (SSE) application (e.g., multi-zone processing/beamforming, noise suppression, etc.), a voice biometrics/wake-up-word processing application, a game training simulation system application, a virtual reality (VR) application, an extended reality (XR) application also known as mixed reality (MR), an augmented reality (AR) application, a virtual assistant (VA) application, a web conferencing application, a video conferencing application, a telephony application, a voice-over-IP application, a video-over-IP application, an Instant Messaging (IM)/“chat” application, a chatbot application, an interactive voice response (IVR) application, a short messaging service (SMS)/multimedia messaging service (MMS) application, a simulation feedback application, a training application, a real-world feedback application, or other application that allows for the simulation of or management of actual current real-world scenarios that can change in real-time based upon user input. In some implementations, tutor process 110 and/or simulation application 120 may be accessed via one or more of client applications 122, 124, 126, 128. In some implementations, tutor process 110 may be a standalone application, or may be an applet/application/script/extension that may interact with and/or be executed within simulation application 120, a component of simulation application 120, and/or one or more of client applications 122, 124, 126, 128. In some implementations, simulation application 120 may be a standalone application, or may be an applet/application/script/extension that may interact with and/or be executed within tutor process 110, a component of tutor process 110, and/or one or more of client applications 122, 124, 126, 128. In some implementations, one or more of client applications 122, 124, 126, 128 may be a standalone application, or may be an applet/application/script/extension that may interact with and/or be executed within and/or be a component of tutor process 110 and/or simulation application 120. Examples of client applications 122, 124, 126, 128 may include, but are not limited to, e.g., an ASR, examples of which may include, but are not limited to, e.g., an ASR application (e.g., modeling, transcription, etc.), a natural language understanding (NLU) application (e.g., machine learning, intent discovery, etc.), a text to speech (TTS) application (e.g., context awareness, learning, etc.), a speech signal enhancement (SSE) application (e.g., multi-zone processing/beamforming, noise suppression, etc.), a voice biometrics/wake-up-word processing application, a game training simulation system application, a web conferencing application, a video conferencing application, a telephony application, a voice-over-IP application, a video-over-IP application, an Instant Messaging (IM)/“chat” application, a chatbot application, an interactive voice response (IVR) application, a short messaging service (SMS)/multimedia messaging service (MMS) application, a feedback application, a training application, or other application that allows for the simulation of scenarios that can change in real-time based upon user input, a standard and/or mobile web browser, an email application (e.g., an email client application), a textual and/or a graphical user interface, a customized web browser, a plugin, an Application Programming Interface (API), or a custom application. The instruction sets and subroutines of client applications 122, 124, 126, 128, which may be stored on storage devices 130, 132, 134, 136, coupled to client electronic devices 138, 140, 142, 144, may be executed by one or more processors and one or more memory architectures incorporated into client electronic devices 138, 140, 142, 144. It will be appreciated after reading the present disclosure that simulation application 120 may similarly be applicable in non-simulation implementations, such as a use as a live Command and Control (C2) application and/or operating system.

In some implementations, one or more of storage devices 130, 132, 134, 136, may include but are not limited to: hard disk drives; flash drives, tape drives; optical drives; RAID arrays; random access memories (RAM); and read-only memories (ROM). Examples of client electronic devices 138, 140, 142, 144 (and/or computer 112) may include, but are not limited to, a personal computer (e.g., client electronic device 138), a laptop computer (e.g., client electronic device 140), a smart/data-enabled, cellular phone (e.g., client electronic device 142), a notebook computer (e.g., client electronic device 144), a tablet, a server, a television, a smart television, a smart speaker, an Internet of Things (IoT) device, a media (e.g., audio/video, photo, etc.) capturing and/or output device, an audio input and/or recording device (e.g., a handheld microphone, a lapel microphone, an embedded microphone/speaker (such as those embedded within eyeglasses, smart phones, tablet computers, smart televisions, smart speakers, watches, etc.), a wearable device (e.g., wearable headset), a virtual reality (VR) wearable, an extended reality (XR) mixed reality (MR) wearable, an augmented reality (AR) wearable, a connected foot-pedal device, a connected handheld pointing device, a biometric sensing device (e.g., an eye tracking sensor), a dedicated network device, and combinations thereof. Client electronic devices 138, 140, 142, 144 may each execute an operating system, examples of which may include but are not limited to, Android™, Apple® iOS®, Mac® OS X®; Red Hat® Linux®, Windows® Mobile, Chrome OS, Blackberry OS, Fire OS, or a custom operating system.

In some implementations, one or more of client applications 122, 124, 126, 128 may be configured to effectuate some or all of the functionality of tutor process 110 (and vice versa). Accordingly, in some implementations, tutor process 110 may be a purely server-side application, a purely client-side application, or a hybrid server-side/client-side application that is cooperatively executed by one or more of client applications 122, 124, 126, 128 and/or tutor process 110.

In some implementations, one or more of client applications 122, 124, 126, 128 may be configured to effectuate some or all of the functionality of simulation application 120 (and vice versa). Accordingly, in some implementations, simulation application 120 may be a purely server-side application, a purely client-side application, or a hybrid server-side/client-side application that is cooperatively executed by one or more of client applications 122, 124, 126, 128 and/or simulation application 120. As one or more of client applications 122, 124, 126, 128, tutor process 110, and simulation application 120, taken singly or in any combination, may effectuate some or all of the same functionality, any description of effectuating such functionality via one or more of client applications 122, 124, 126, 128, tutor process 110, simulation application 120, or combination thereof, and any described interaction(s) between one or more of client applications 122, 124, 126, 128, tutor process 110, simulation application 120, or combination thereof to effectuate such functionality, should be taken as an example only and not to limit the scope of the disclosure.

In some implementations, one or more of users 146, 148, 150, 152 may access computer 112 and tutor process 110 (e.g., using one or more of client electronic devices 138, 140, 142, 144) directly through network 114 or through network 118. Further, computer 112 may be connected to network 114 through network 118, as illustrated with phantom link line 154. Tutor process 110 may include one or more user interfaces, such as browsers and textual or graphical user interfaces, through which users 146, 148, 150, 152 may access tutor process 110.

In some implementations, the various client electronic devices may be directly or indirectly coupled to network 114 (or network 118). For example, client electronic device 138 is shown directly coupled to network 114 via a hardwired network connection. Further, client electronic device 144 is shown directly coupled to network 118 via a hardwired network connection. Client electronic device 140 is shown wirelessly coupled to network 114 via wireless communication channel 156 established between client electronic device 140 and wireless access point (i.e., WAP 158), which is shown directly coupled to network 114. WAP 158 may be, for example, an IEEE 802.11a, 802.11b, 802.11 g, 802.11n, 802.11ac, Wi-Fi®, RFID, and/or Bluetooth™ (including Bluetooth™ Low Energy) or any device that is capable of establishing wireless communication channel 156 between client electronic device 140 and WAP 158. Client electronic device 142 is shown wirelessly coupled to network 114 via wireless communication channel 160 established between client electronic device 142 and cellular network/bridge 162, which is shown by example directly coupled to network 114.

In some implementations, some or all of the IEEE 802.11x specifications may use Ethernet protocol and carrier sense multiple access with collision avoidance (i.e., CSMA/CA) for path sharing. The various 802.11x specifications may use phase-shift keying (i.e., PSK) modulation or complementary code keying (i.e., CCK) modulation, for example. Bluetooth™ (including Bluetooth™ Low Energy) is a telecommunications industry specification that allows, e.g., mobile phones, computers, smart phones, and other electronic devices to be interconnected using a short-range wireless connection. Other forms of interconnection (e.g., Near Field Communication (NFC)) may also be used. In some implementations, computer 112 may be directed or controlled by an operator. Computer 112 may be hosted by one or more of assets owned by the operator, assets leased by the operator, and third-party assets. The assets may be referred to as a private, community, or hybrid cloud computing network or cloud computing environment. For example, computer 112 may be partially or fully hosted by a third party offering software as a service (SaaS), platform as a service (PaaS), and/or infrastructure as a service (IaaS). Computer 112 may be implemented using agile development and operations (DevOps) principles. In some implementations, some or all of computer 112 may be implemented in a multiple-environment architecture. For example, the multiple environments may include one or more production environments, one or more integration environments, one or more development environments, etc.

In some implementations, various I/O requests (e.g., I/O request 115) may be sent from, e.g., client applications 122, 124, 126, 128 to, e.g., computer 112 (and vice versa). Examples of I/O request 115 may include but are not limited to, data write requests (e.g., a request that content be written to computer 112) and data read requests (e.g., a request that content be read from computer 112). Client electronic devices 138, 140, 142, 144 and/or computer 112 may also communicate audibly using an audio codec, which may receive spoken information from a user and convert it to usable digital information. An audio codec may likewise generate audible sound for a user, such as through a speaker, e.g., in a handset of a client electronic device. Such sound may include sound from voice telephone calls, may include recorded sound (e.g., voice messages, music files, etc.) and may also include sound generated by applications operating on the client electronic devices.

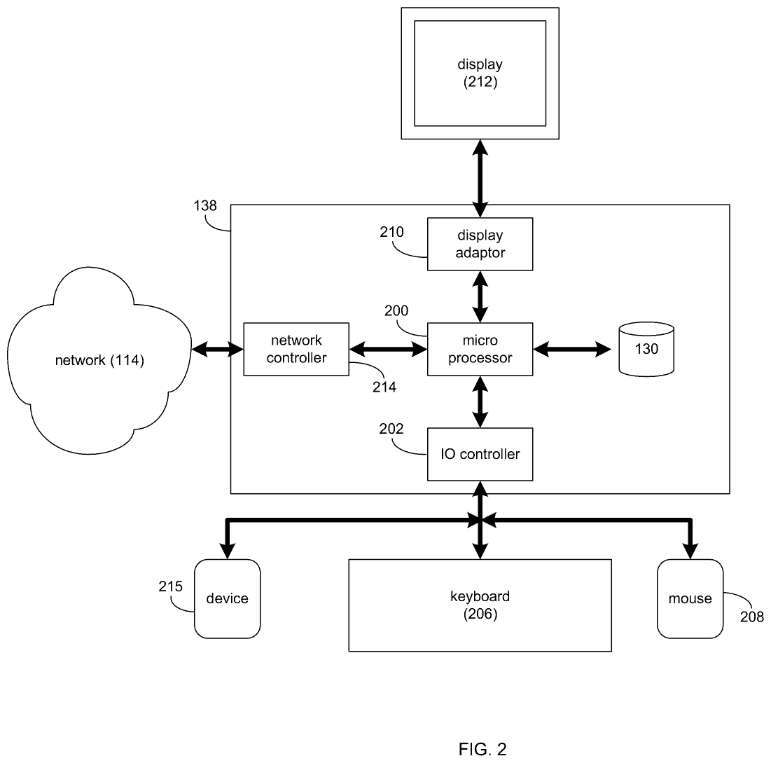

Referring also to the example implementation of FIG. 2, there is shown a diagrammatic view of client electronic device 138. While client electronic device 138 is shown in this figure, this is for example purposes only and is not intended to be a limitation of this disclosure, as other configurations are possible. Additionally, any computing device capable of executing, in whole or in part, tutor process 110 may be substituted for client electronic device 138 (in whole or in part) within FIG. 2, examples of which may include but are not limited to computer 112 and/or one or more of client electronic devices 138, 140, 142, 144.

In some implementations, client electronic device 138 may include a processor (e.g., microprocessor 200) configured to, e.g., process data and execute the above-noted code/instruction sets and subroutines. Microprocessor 200 may be coupled via a storage adaptor to the above-noted storage device(s) (e.g., storage device 130). An I/O controller (e.g., I/O controller 202) may be configured to couple microprocessor 200 with various devices (e.g., via wired or wireless connection), such as keyboard 206, pointing/selecting device (e.g., touchpad, touchscreen, mouse 208, etc.), scanner, custom device (e.g., device 215), USB ports, and printer ports. A display adaptor (e.g., display adaptor 210) may be configured to couple display 212 (e.g., touchscreen monitor(s), plasma, CRT, or LCD monitor(s), etc.) with microprocessor 200, while network controller/adaptor 214 (e.g., an Ethernet adaptor) may be configured to couple microprocessor 200 to network 114 (e.g., the Internet or a local area network).

Generally speaking, Command and Control (C2) is the exercise of authority and direction by a properly designated individual over assigned and attached forces, assets, or personnel in the accomplishment of a mission/goal. It typically involves a range of operational processes, systems, and organizational structures. In essence, C2 is about making timely and informed decisions and ensuring that the necessary resources (e.g., troops, vehicles, equipment, etc.) are available and effectively employed to achieve mission objectives. C2 may cover the spectrum of, e.g., commercial, emergency management, and military applications for the safe and effective conduct of operations in diverse environments and conditions.

C2 management is a challenging skill that generally may require deep knowledge of tactics, techniques, and procedures (TTPs). When managing a C2 operation or network, a C2 manager or operator may use various communication methods including, e.g., radios and other technologies to exercise the following example and non-limiting responsibilities:

1. Maintain Situational Awareness: (i) Continuously monitor all available information sources to have a comprehensive and current picture of the operational environment; (ii) Use various sensors, intelligence reports, and input from personnel in the field to update the operational picture; (iii) Identify any emerging threats or challenges to the mission.

2. Manage communications to facilitate clear and effective understanding among all units and teams.

3. Provide decision support by delivering timely and accurate information to assist in decision-making and offer recommendations based on the evolving situation and available resources.

4. Prioritize and allocate resources effectively based on the mission requirements and evolving situations and coordinate the activities of various units to ensure they are working in harmony and not at cross-purposes.

5. Plan and direct operations by developing plans and strategies based on the commander's intent and the current situational picture, adjusting plans as the situation evolves, and directing subordinate units and personnel in the execution of the mission.

6. Information assurance and security support to protect communication and information systems from cyber threats and eavesdropping.

7. Provide liaison, coordination, and deconfliction by establishing and maintaining communication with other entities, such as allied forces, civilian authorities, and NGOs.

8. Maintain logs and records of operations, decisions, and communications that can be important for after-action reviews, investigations, and continuous improvement efforts.

9. Continuously assess potential risks and threats to the mission and develop and implement measures to mitigate those risks.

A successful C2 manager typically facilitates a harmonious and efficient operational environment, empowering all assets to perform at their peak, while responding promptly and effectively to emerging challenges.

Individuals who have no prior experience in C2 operations need to learn the baseline skill of how to properly communicate within the context of their mission and role within a system. Standardized communications in C2 operations often require use of specific doctrine, procedures, communications format, and techniques that must be practiced and memorized prior to conducting more complex training. In addition to knowing how to communicate critical information, individuals must learn how to derive the information quickly and accurately from their operating system that is to be communicated (also known as a “scan pattern”). These fundamental skills are only learned through repetition and need to escalate in complexity only at the rate in which the individual student can become proficient (i.e., if the complexity is increased too quickly, the student may start to fall behind). Additionally, individuals require continuous professional development and proficiency training to maintain required skills and performance, as environments, doctrine, and TTPs evolve over time throughout their career lifecycle.

Equally important are proficiency and experience in real-world situations that require C2 personnel to use their knowledge to solve problems and handle threats to performance and successful outcomes. Lack of experience and proficiency can have catastrophic consequences, resulting in the loss of time and increased costs, loss of equipment, and worse, the loss of life. Even with a sufficiently experienced and proficient operator, there is still the risk of making a human error during complex or stressful situations.

Due to the complex nature of C2 operations, proper training is important to expanding the breadth of experience and proficiency of operators and the use of training simulation systems is often the only way to train toward complex TTPs due to live resource constraints and safety limitations. The use of full simulation training systems generally requires significant time, personnel, and costly simulator infrastructure. Due to these factors, training time in simulators is often constrained to complex scenarios that significantly reduce the opportunity to train and practice core competencies, such as communications. Additionally, these training events are typically linear, scripted scenarios that are inflexible to the needs and abilities of individual students. It is often the case that self-guided, self-paced learning is unavailable for both students and qualified operators outside of scheduled simulator training events. Individuals also usually rely on subjective human feedback during both training and real-world operations as the only means to learn from their training, which provides an inconsistent learning environment.

Additionally, C2 operators typically lack real-time tools to provide them with feedback on their performance during routine or complex operations without backup support or monitoring from another human. Real-time feedback of this nature could be important to avoid errors due to complacency or other latent sources of operational risk, as well as to mitigate against task saturation and loss of situational awareness during high-workload complex operations, such as tactical intercept control, airspace surveillance, air traffic control, port and harbor operations, etc.

Therefore, as will be discussed in greater detail below, the present disclosure may solve the example and non-limiting problems specifically associated with C2 training and operations software to build knowledge and skills across the full range of C2 manager responsibilities by, e.g.:

1. Providing objective performance feedback through a combination of game state data, player performance data, and human performance biometrics.

2. Providing feedback in real-time during training and operations.

3. Providing interactive post training event debrief feedback using objective performance-based metrics, biometrics data, and AI/ML performance predictions.

4. Simulating real-time actions and interactive communications with operational entities through the example use of a non-player character (NPC) to reduce the need for live human role players.

5. Enabling training without the need of support from instructors, human or human controlled role players, conventional simulation systems, and live operational training resources, such as, e.g., aircraft and radar systems.

6. Providing a mobile training system solution that does not require a fixed simulator infrastructure and may be executed on nearly any computing device.

As will also be discussed in greater detail below, the present disclosure may overcome the example challenges of Initial Qualification Training (IQT) and follow-on proficiency training for C2 students and operators by providing unique mobile computer-based training capabilities. Users of the present disclosure may conduct self-guided training nearly anytime and anywhere, reducing instructor workload, as well as high cost and dependency on legacy fixed simulator infrastructure. The present disclosure may use voice-interactive NPCs in tailored scenarios to provide the repetitions in play and training needed to develop and maintain C2 skills in any operational context that uses a standardized (or non-standardized) operating construct. The present disclosure may have both military applications that apply across all service components, as well as commercial applications that may include, e.g.: Air-to-air Tactical Intercept control (e.g., applies to both controllers and fighter aircrew), Close Air Support/Deep Air Support, US Navy Maritime operations, Military and Civil Air Traffic Control, Commercial shipping operations (Seaspeak, harbormaster, etc.), Emergency management, Multi-domain surveillance (air, sea, subsurface, cyber, electronic warfare, etc.), Space operations, etc.

The present disclosure may include an embedded and/or remote intelligent tutoring system that may use human game performance, voice, eye tracking and/or other biometric data to provide real-time feedback to students during scenario execution. By integrating multiple AI paradigms—including predictive analytics (e.g., MLBAM), rules-based logic (e.g., RBTE), and prescriptive analytics—the system transcends simpler scripted or static branching methodologies, enabling more nuanced and adaptive scenario shaping. This data may be used to provide on-the-fly Adaptive Learning Events (ALEs) (also described as an intervention event) that enforce positive performance and offer interventions to correct errors in real-time while proactively prescribing scenario adjustments that enhance individualized training outcomes and respond dynamically to latent human factors such as cognitive load or situational awareness degradation. Artificial Intelligence and Machine Learning (AI/ML) models may be incorporated into predictive algorithms that may intervene with an ALE prior to a user error occurring. It will be appreciated after reading the present disclosure that other types of AI-based learning models may be used, such as those discussed throughout.

In some implementations, the present disclosure may include cloud-based replay and debrief tools that may give students and instructors (or other types of users) unparalleled insight into individual performance by providing objective, event-based feedback between, e.g., expected and actual communications in the areas of accuracy, completeness, comprehension, and timeliness. Every scenario playthrough may provide a debrief that displays every graded scenario event in timeline order. The player may be able to step through each event and in the case where there is communicated interaction with the NPC, the player may scroll through the mission timeline while viewing the sensor display and listen to the audio playback and is provided feedback on the expected communication elements versus their actual communication. The debrief tool of the present disclosure may provide the following example and non-limiting feedback about communications within visual context of the tactical scenario picture:

(1) Text of the specific communications verbiage recorded from the player.

(2) Text of the communication expected to be said by the player to make given the current tactical picture.

(3) Discrepancies between the actual communication recorded by the player and expected communication.

(4) Explanatory information for each intervention provided, including a description of why the intervention was triggered.

In some implementations, all debriefs may be saved locally and/or in cloud-based storage, and may be viewed by instructors and students at their leisure.

In some implementations, the present disclosure may be adapted and integrated into operational C2 systems to provide feedback and real-time backup during real-world operations. By blending predictive analytics (e.g., MLBAM), rules-based logic (e.g., RBTE), and prescriptive analytics (e.g., Tutor Process) into a unified, intelligent framework, this system surpasses traditional scripted or static training methods. It monitors and leverages human performance biometrics (e.g., gaze, voice cadence, pupillometry) alongside conventional performance metrics to detect latent cognitive load, situational awareness gaps, and other hidden factors before errors occur, thereby enabling real-time Adaptive Learning Events (ALEs) that proactively adjust difficulty, adjust cues/prompts, and adjust agent behaviors. Not only can it excel in Command and Control (C2) scenarios, but its flexible architecture extends to a wide range of domains, including military, commercial, emergency management, and beyond. For example, it can support medical training simulations (e.g., surgical procedures, emergency room triage), high-stress civilian operations (e.g., firefighting, policing, air traffic control), complex industrial plants (e.g., nuclear or chemical processing), corporate and financial decision-making (e.g., supply chain or trading environments), and even educational contexts (e.g., language learning, STEM education, professional skill development). In each of these example applications, the system moves from retrospective debrief-based learning to continuous, embedded learning that prescribes scenario adjustments to actively shape and improve human performance outcomes. In some implementations, the present disclosure may be a separate application from the operational C2 systems.

In some implementations, the present disclosure may also be integrated into large scale live, virtual, and constructive (LVC) training architectures to supplement training scenarios by filling in gaps in the live play C2 exercise structure during multi-domain training operations. In this example use case, live human training participants, or “players” in a distributed LVC training event may select from a menu of non-player characters (NPC) in a massive multiplayer online architecture. These NPCs may then provide the appropriate actions and communications to fill the role of the missing players.

As mentioned previously, existing solutions are those legacy training systems are costly, manpower intensive, and schedule driven. On the other hand, the present disclosure enables cost-effective, self-guided, and mobile training with a small footprint (with an optional portable) system. The present disclosure may provide on-demand training to those spanning from novice to expert users through dynamic training events assisted by the augmented scenarios of the present disclosure. Moreover, by incorporating more granular personalization (e.g., individualized difficulty curves and custom cueing), expanding sensor integration (e.g., EEG headbands, additional physiological sensors), and ensuring interoperability with standard simulation protocols, the approach can scale to diverse domains beyond Command and Control, such as medical training simulations, high-stress civilian operations (e.g., firefighting, policing), industrial control rooms, financial decision-making scenarios, and even educational contexts where adaptive tutoring tailors difficulty to cognitive engagement levels. The scenarios may be replayed as many times as needed or desired to achieve training objectives with the player and immediate performance feedback may be provided through the debrief system upon completion of that scenario, and/or in real-time during the on-going scenario.

Example and non-limiting benefits of the present disclosure may include, e.g., Mobile and portable training kit; Software licensing structure to provide continued support and software updates/bug fixes; Software architecture allowing the present disclosure to be adaptable and flexible to different mission needs and communication standard changes; Automated, simulated, self-guided training; Automated assessment of communications and decision-making skills including timeliness, accuracy, completeness, and adherence to standards and doctrine; Automated real-time performance assessment and evaluation; Real-time adaptive learning events tailored to performance deficiencies to improve learning and enhance performance; Use of human performance biometrics to improve quality of performance assessments, feedback, and adaptive learning events; AI predictions of human performance based on trained ML model to improve adaptive learning events, maintain performance within the zone of proximal development and serve as a virtual instructor or mentor; AI-based models may be used to provide predictive feedback during real-world operations (or training) as a form of virtual mentoring and back-up.

As will be discussed below, tutor process 110 may at least help, e.g., improve simulation technology, necessarily rooted in computer technology, in order to overcome an example and non-limiting problem specifically arising in the realm of computer-based simulations and to improve existing technological processes associated with such simulations. Some implementations may include granular personalization by incorporating individualized difficulty curves, tailored cueing styles, and custom interventions informed by a user's historical patterns, as well as sensor integration beyond eye tracking and voice biometrics to include wearable EEG devices or other advanced physiological sensors could enable earlier detection of cognitive overload or stress. Some implementations may also include interoperability enhancements by incorporating standard simulation protocols (e.g., DIS, HLA) and introducing scalable authoring tools that leverage AI-driven rule generation and automated scenario configuration to streamline integration into diverse training infrastructures. These attributes only bolster the system's adaptability and portability but also facilitate rapid deployment across multiple operational, commercial, and educational ecosystems. Unlike conventional solutions that rely on fixed, scripted scenarios or linear branching logic, the present disclosure introduces a clever integration of predictive analytics (e.g., MLBAM), rules-based engines (e.g., RBTE), and prescriptive analytics to dynamically shape training environments in real-time. By leveraging multimodal biometric and performance data, as well as various communication inputs (e.g., voice, chat, data link), the system identifies latent cognitive or situational awareness issues before they cause performance breakdowns. These proactive interventions, which can be deployed flexibly across on-premises or cloud-based infrastructures, and applied to a wide range of domains, represent a departure from traditional after-action review models. Moreover, the seamless adaptability of Non-Player Characters (NPCs) to fill critical roles in live, virtual, and constructive (LVC) training architectures is one example and non-limiting aspect that sets this approach apart. Consequently, the innovations described herein deliver a fundamentally different and more robust paradigm for enhancing human performance under complex conditions, establishing a unique standard for simulation-based learning and decision support. Tutor process 110 is being integrated into the practical application of, for example, updating simulation scenarios in real-time for its simulations based upon real-time and/or predicted inputs from the user/simulation performance with example command and control training games. It will be appreciated that the computer processes described throughout are integrated into one or more practical applications, and when taken at least as a whole are not considered to be well-understood, routine, and conventional functions.

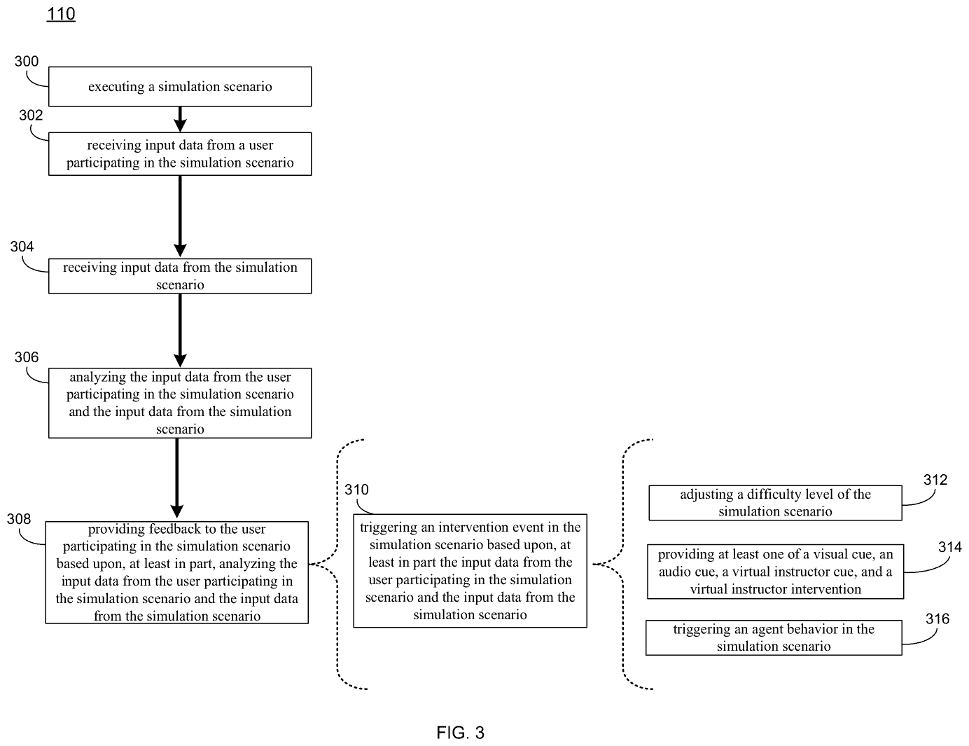

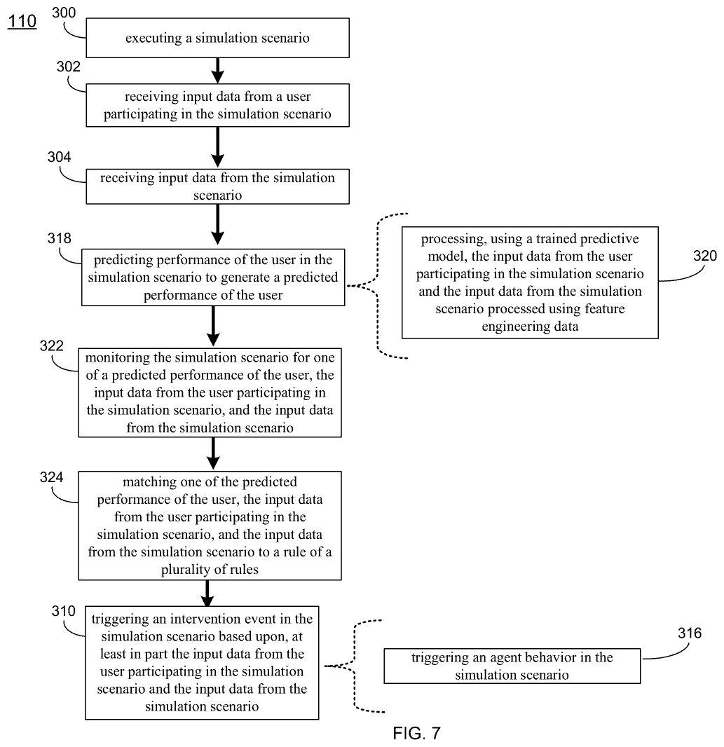

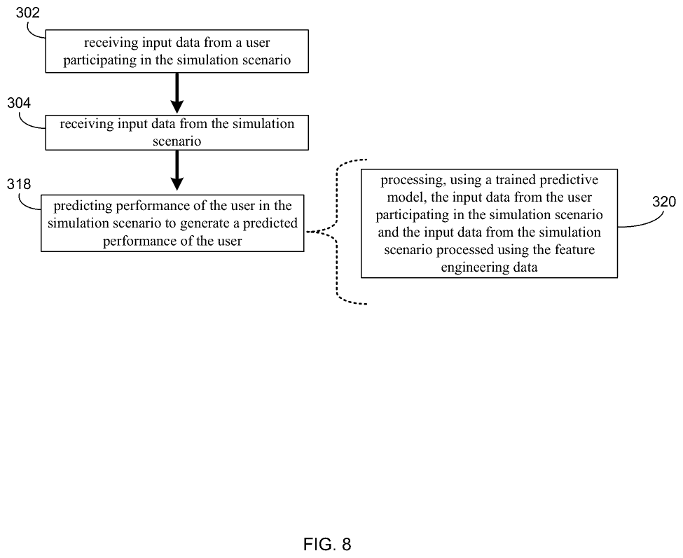

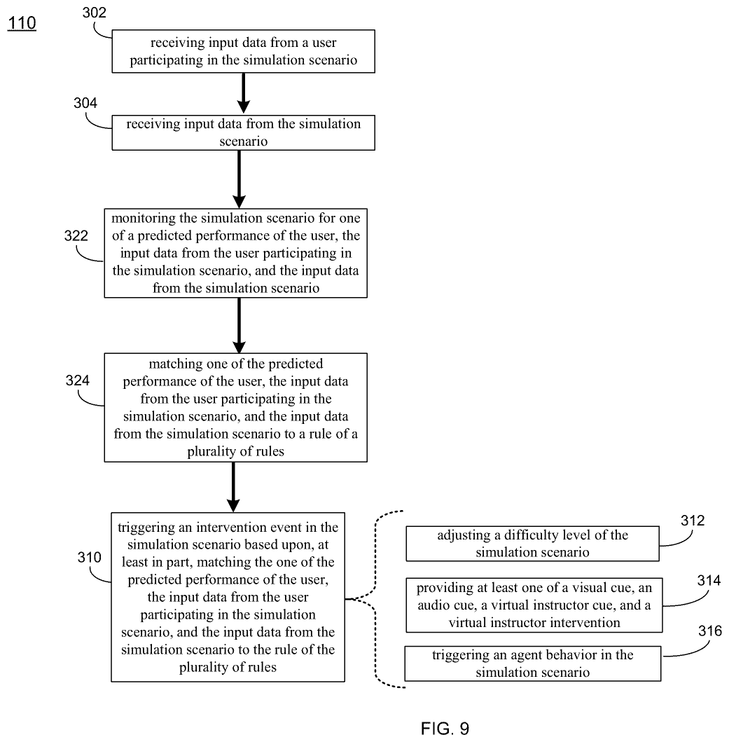

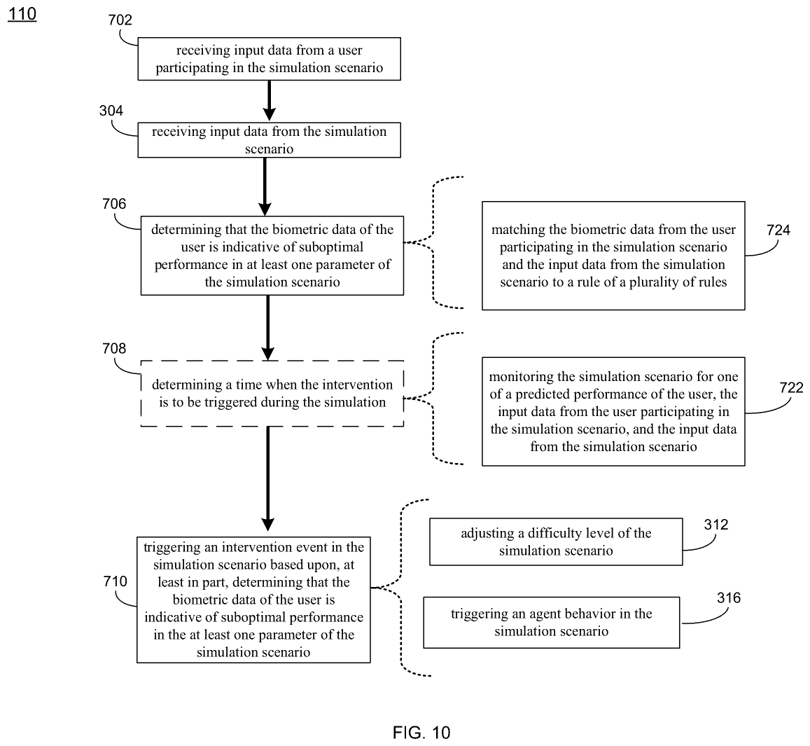

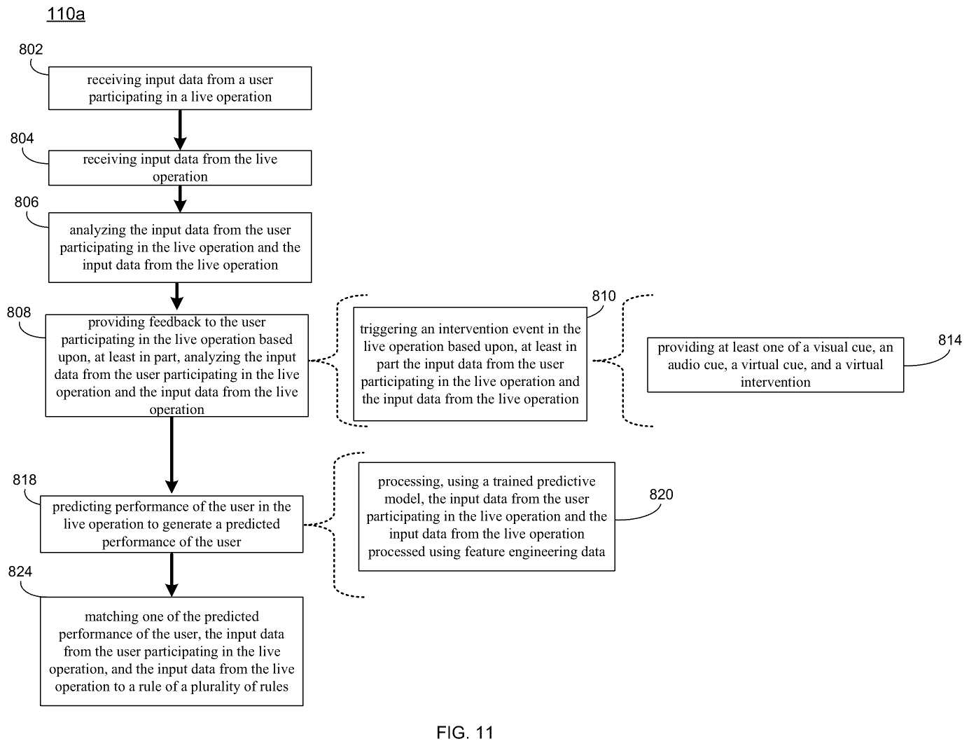

As discussed above and referring also at least to the example implementations of FIGS. 3-12, tutor process 110 may execute 300 a simulation scenario. Tutor process 110 may receive 302 input data from a user participating in the simulation scenario. Tutor process 110 may receive 304 input data from the simulation scenario. Tutor process 110 may analyze 306 the input data from the user participating in the simulation scenario and the input data from the simulation scenario. Tutor process 110 may provide 308 feedback to the user participating in the simulation scenario based upon, at least in part, analyzing the input data from the user participating in the simulation scenario and the input data from the simulation scenario.

The following description involves a serious game training and/or real-world simulation system for C2 applications; however, it will be appreciated after reading the present disclosure that any type of applications and any types of simulation purposes may be used with the present disclosure. As such, the description of a serious game training and/or real-world simulation system for C2 applications should be taken as example only and not to otherwise limit the scope of the present disclosure. It will also be will be appreciated after reading the present disclosure that while an advantage of the present disclosure is the ability to be executed on a local client electronic device, the functionality of tutor process 110 may also be executed using the above-noted legacy training systems without departing from the scope of the present disclosure.

The term “serious game” as used herein refers broadly to training simulations that leverage interactive, scenario-based designs to facilitate skill development and operational decision-making. This includes, but is not limited to, gamified environments and non-gamified simulation platforms that replicate real-world systems or scenarios for educational or operational purposes. These serious game and training simulations provide immersive, adaptable, and interactive environments to develop and enhance operator proficiency in complex operational contexts. In some implementations, tutor process 110 may execute 300 a simulation scenario. For instance, as will be discussed in greater detail below, tutor process 110 enables a serious game training simulation system accessed through an application (e.g., simulation application 120) installed on a mobile training device (e.g., such as client electronic device 138, 144, 142, etc. from FIG. 1 and/or FIGS. 2-3) using, e.g., a USB or installed on other connected wearable (e.g., headset, VR/XR eyewear, etc.), connected foot-pedal device, a connected handheld pointing device (mouse), eye tracking sensor, or any other client electronic device or peripheral device. Tutor process 110 may access the internet through an ethernet connection or other wired/wireless methods/network(s), such as those discussed throughout, which may also be used to download simulation application 120 to run locally and/or run simulation application 120 remotely. Data services, as used herein, may generally refer to the storage, retrieval, and management of game-related data, whether hosted on local servers, cloud-based infrastructure, or a hybrid combination thereof. Voice services may generally refer to AI-enabled natural language processing capabilities (e.g., ASR, NLU, NLP, etc.) for, e.g., converting speech to text and text to speech, implemented on client devices, on-site systems, cloud resources, or through hybrid configurations. Data and/or voice services may be installed locally on client electronic device 138 without the need for connection to any form of commercial internet, and/or through commercial/government networks. In some implementations, simulation application 120 and/or tutor process 110 may be supported via a web-based data architecture, on premises network and data storage, or hybrid cloud that uses a combination of local on-premises, cloud, and client data architecture components.

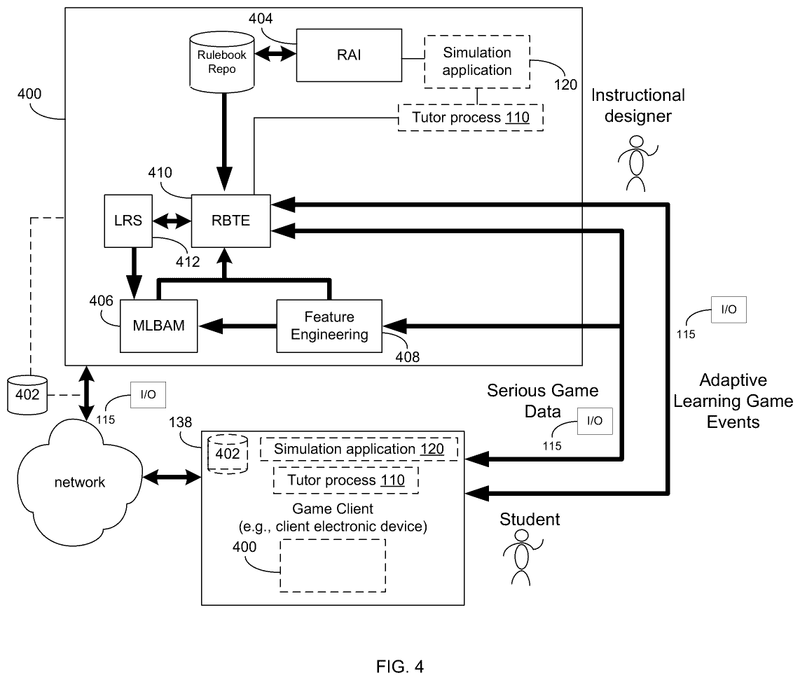

In some implementations, as will be discussed further below, data may be captured by tutor process 110 within a serious game application and may communicate with a datastore (or other type of storage architecture) to access such things as, e.g., user authentication information, user assessment data, user training options, user feedback, previous user training events view information, user logins, application updates, organization information, application logs, and various other tutor process 110 information. In Some implementations, tutor process 110 may integrate multiple processes to deliver a comprehensive, adaptive, and proactive training environment. For example, the Machine Learning Biometric Assessment Module (MLBAM) portion of tutor process 110 may apply predictive analytics to user biometrics (e.g., gaze, voice cadence, pupillometry) and conventional performance measures, identifying hidden performance factors like cognitive load before errors occur. The Rules-Based Tutoring Engine (RBTE) portion of tutor process 110 may then leverage these predictive insights to match conditions against authored rule sets, ensuring that Adaptive Learning Events (ALEs) can be triggered in real-time. In some implementations, tutor process 110 may employ prescriptive analytics to not only anticipate user needs but also prescribe scenario adjustments and cueing strategies that shape improved human performance. This unified approach transcends simple scripted scenarios or static decision trees, enabling continuous, embedded learning across a range of domains, and is further poised for enhancements in personalization, sensor integration, interoperability, and scalable authoring-ultimately supporting diverse applications from military C2 environments to medical training, industrial control systems, and educational skill development. For instance, and referring at least to the example implementation of FIG. 4, an example simulation system (e.g., simulation system 400) is shown. In the example, the above-noted datastore (e.g., datastore 402) may be operatively connected to the gaming client (e.g., such as client electronic device 138, 144, 142, etc. from FIG. 1 and/or FIGS. 2-3). For ease of explanation, assume that the game client is client electronic device 138. These capabilities may also be deployed on a wide range of architectures, including but not limited to on-premises servers, mobile or transportable servers, web-based game instances, and hybrid configurations, thus providing flexible deployment options that can be tailored to diverse operational constraints or network topologies.

As will be discussed in greater detail below, simulation system 400 may also include a Rule Authoring Interface (RAI), such as RAI 404, a Machine Learning Biometric Assessment Module (MLBAM), such as MLBAM 406, a feature engineering engine module, such as feature engineering module 408, a Rules Bases Tutoring Engine (RBTE) Module, such as RBTE 410, and Learning Record Store (LRS), such as LRS 412. It will be appreciated after reading the present disclosure that the components of simulation system 400 may vary in their configuration and placement, and that more or less components may be used and/or combined and/or replaced without departing from the scope of the present disclosure. It will also be appreciated after reading the present disclosure that tutor process 110 and/or simulation application 120 (as well as any portion of their functionality) may be part of simulation system 400 or any of the components of simulation system 400 (and vice versa), and that simulation system 400 (e.g., via tutor process 110 and/or simulation application 120) may be a part of client electronic device 138 and may be connected wirelessly or wired to client electronic device 138 via the network. It will also be appreciated after reading the present disclosure that various alternative architectures of simulation system 400 and/or client electronic device 138 may also be used to monitor game data, player performance data, and human performance biometrics to assess the need for, and trigger, Adaptive Learning Events (ALEs), or other interventions, including variations that do not use eye tracking or one or more other biometrics as a trigger/intervention parameter. As such, the example configurations shown in the figures and described throughout should be taken as example only and not to otherwise limit the scope of the present disclosure.

In some implementations, information and simulation training may be accessed through a range of UI pages in simulation application 120 (e.g., via tutor process 110). Information about such things as previous training events, organization information, user information, and training options, etc., may be accessed by simulation application 120 (e.g., via tutor process 110) through, e.g., a main menu UI (e.g., via RAI 404) that provides access to detailed information about each individual category. The main menu (e.g., via tutor process 110 and/or simulation application 120) may enable users to do such things as, e.g., select from available training scenarios, initiate play, review mission playback and debrief, and access a scoring leaderboard that allows a player or teacher to assess their performance against their personal play history, as well as their peers within or external to their organization.

Generally, training scenarios may include numerous entities with numerous key attributes to define performance and behaviors during play. This information may be stored, e.g., in datastore 402. While the following example includes aircraft entities, it will be appreciated after reading the present disclosure that other types of entities may be used without departing from the scope of the present disclosure. For example:

1. Individual and groups of entities associated with key metadata varying by role in the scenario. For instance, aircraft entities may include metadata such as type/model/series, performance parameters, starting conditions, position, altitude, speed, heading, cargo or passenger capacity, flight plan, and communication logs. Other types of entities may include:
(a) Ground vehicles, which may include type (e.g., emergency response, cargo, passenger transport), current position, speed, heading, cargo or passenger status, fuel level, and route information.
(b) Naval vessels, which may include type/model, displacement, speed, heading, cargo, passenger or crew count, status of onboard systems (e.g., radar, communication), and docking schedules.
(c) Personnel, which may include roles (e.g., responders, coordinators, operators), current position, assigned tasks, skill certifications, health status, and communication or coordination logs.
(d) Unmanned systems, which may include type (e.g., drones, unmanned ground vehicles, submersibles), battery level, payload type (e.g., surveillance, delivery), operational range, and communication protocols.
(e) Infrastructure, which may include fixed installations (e.g., command centers, communication towers, warehouses, docks, and piers) with associated operational status, capacity, and access restrictions.
(f) Sensors, which may include devices such as weather stations, cameras, harbor radars, or traffic sensors, with metadata like detection range, accuracy, operational status, and data output type.
(g) Environmental factors, which may include dynamic entities such as weather systems (e.g., storms, wind speed), tidal movements, sea state, traffic congestion, or hazardous areas.
(h) Cargo and freight, which may include shipments, containers, or goods with metadata such as weight, dimensions, contents, destination, tracking information, and security status.
(i) Passengers, which may include metadata such as group size, demographics, boarding status, and destination.
(j) Cyber entities, which may include virtual assets like simulated networks, communication nodes, or data streams with metadata such as encryption level, bandwidth, latency, and security alerts.

It will be appreciated after reading the present disclosure that other entities may also be associated with key metadata without departing from the scope of the current disclosure.

2. Flight path information, which may be defined by waypoints or established at run time using agent entity behaviors and including additional performance metadata including, e.g., aircraft group owner, position, maneuvers in heading or altitude, velocities and acceleration or deceleration, arrival information, etc.

3. Boolean parameter flags, which save scenario events and provide game and player performance information on events during game play.

4. Scenarios may include, e.g., trigger events, which initiate actions performed by game entities, as will be discussed in greater detail below. Trigger logic may be derived from rule-based algorithms, predictive analytics, or a hybrid of the two. It will be appreciated after reading the present disclosure that more or less or other key attributes to define performance and behaviors during play of the scenario may also be used without departing from the scope of the present disclosure.

As will be discussed in greater detail below, in some implementations, scenarios may play out by, e.g., aircraft groups executing a flight profile, events being triggered by in-scenario actions, and player input by a peripheral device, such as a keyboard, pointing device, microphone, etc., and making expected communications that may be interpreted (e.g., via speech recognition application of tutor process 110) and graded (e.g., comparing what was said by the player with what should have been said according to proper protocols and standards).

In some implementations, tutor process 110 may receive 302 input data from a user participating in the simulation scenario. For instance, in some implementations, the input data (e.g., I/O request 115) from the user participating in the simulation scenario may include user biometrics (e.g., gaze tracking, gaze association with objects, entities, and dwell time, pupillometry, voice parameters, heart rate, respiration rate, brain activity, or other parameters), user performance data (e.g., experience level, performance history, currency of performance and training, UI input actions, communications calls and other performance measures, etc.).

In some implementations, tutor process 110 may receive 304 input data from the simulation scenario. For instance, in some implementations, the input data (e.g., I/O request 115) from the simulation scenario may include game state data (e.g., defining scenarios, start and ending conditions, game entities, entity behaviors, event data or other game data). In some implementations, input data from the user or the simulation scenario may be received and stored in memory or other storage device type for access and/or analysis.

In some implementations, tutor process 110 may analyze 306 the input data from the user participating in the simulation scenario and the input data from the simulation scenario, and in some implementations, tutor process 110 may provide 308 feedback to the user participating in the simulation scenario based upon, at least in part, analyzing the input data from the user participating in the simulation scenario and the input data from the simulation scenario. This analysis may extend beyond voice inputs, sensor streams, and biometric signals to include chat communications, data link messages, text-based exchanges, and other non-verbal communication pathways between the player (or operator) and non-player characters (NPCs), as well as between operators in real-world operations. By interpreting and assessing these additional data sources, the system may trigger appropriate scenario adjustments, interventions, or ALEs, ensuring comprehensive monitoring and guidance across multiple communication modalities. For instance, tutor process 110 may take the input from simulation system 400 such as game events, aircraft group positions, player performance (e.g., current and/or historical), and human performance biometrics information, including, e.g., eye tracking, to provide to both feature engineering module 408 and RBTE 410 module. Feature engineering module 408 (e.g., via tutor process 110) may perform programmed engineering, which involves computationally processing and transforming raw data inputs (e.g., eye tracking metrics such as gaze duration or pupil dilation) into structured features that are optimized for use in predictive models. These engineered features may then be sent to MLBAM 406 to make (e.g., via tutor process 110) predictions about player performance. For example, eye tracking metrics may be used to infer cognitive load, situational awareness, or reaction times, which are incorporated into predictive algorithms to assess and forecast a player's ability to maintain task performance under varying conditions. These predictions may then be sent to RBTE 410, which may match the results to predefined rules or generate adaptive and prescriptive interventions. LRS 412 (e.g., via tutor process 110) may send previous (historical) data, as well as new outputs of RBTE 410. In some implementations, players may receive feedback during play in real-time, as well as during post run debriefs.

In some implementations, providing feedback to the user participating in the simulation scenario may include triggering 310 an intervention event in the simulation scenario based upon, at least in part the input data from the user participating in the simulation scenario and the input data from the simulation scenario. For example, as will be discussed in greater detail below, RBTE 410 may (e.g., via tutor process 110) process the above-noted data inputs and monitor play to identify event parameters that call for initiation of appropriate intervention events, also referred to herein as Adaptive Learning Events (ALE). When RBTE 410 (e.g., via tutor process 110) identifies a trigger for a particular ALE, tutor process 110 may command an ALE to fire (trigger) in the simulation running on client electronic device 138. MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBTE 410. In some implementations, processed data may include game state and event data, player performance data, and human performance biometrics data, etc. At the heart of MLBAM 406 is a predictive model (e.g., of tutor process 110) that may be pre-trained on historical performance data (e.g., user input data and/or simulation scenario input data) to recognize player patterns and deviations from the new, real-time input data of the currently running simulation. In some implementations, the training data may include the following example and non-limiting variables:

1. Independent Variables (IV) such as:
(a) Game state data defining scenarios, start and ending conditions, game entities, entity behaviors, event data or other game data.
(b) Player performance data including experience level, performance history, currency of performance and training, UI input actions, communications calls and other performance measures.
(c) Player human performance biometrics including gaze tracking, gaze association with entities and dwell time, pupillometry, voice parameters, and potentially heart rate, respiration rate, brain activity or other physiology parameters being monitored in response to stimulus and/or stressors of game play.

2. Dependent or Predictor Variables including:
(a) Measures of communication performance and effectiveness such as timeliness, accuracy, completeness, and adherence to standards or other measures.
(b) Measures of event or mission outcomes.

Generally, the pre-trained model may serve as MLBAM 406 decision making entity. MLBAM 406 predictions may be relayed (e.g., via an output interface) to RBTE 410 where they may be processed by tutor process 110 with additional rules-based algorithms and evaluated as potential ALE triggers. One such example is the use of voice cadence to determine whether the player is speaking too fast or too slow. The simulation records spoken words-per-minute (WPM) as an Independent Variable and compares that value to a rule that provides a lower and upper WPM limit. If the WPM IV is above or below the rule's value, then an ALE is triggered that tells the player to “watch their comm cadence.”

In some implementations, triggering the intervention event may include at least one of adjusting 312 a difficulty level of the simulation scenario. For example, ALEs may be used to help keep the player in the zone of proximal development and adapt to their skill level and learning needs, so they will improve at the optimum rate. When a student is being challenged at a high level, ALEs may be triggered that will provide assistance or implement subtle changes in play that reduce difficulty level. Conversely, ALEs may be initiated during play to make scenarios more challenging for a high performing student or player so they will be pushed to develop higher level skills more quickly. In some implementations, triggering the intervention event may include providing 314 at least one of a visual cue, an audio cue, a virtual instructor cue, and a virtual instructor intervention. For instance, a few examples of simulation application's ALEs may include the simulation entities taking advantage of player mistakes by increasing their speed, exploiting a tactical advantage or conducting additional maneuvers, or they may reduce the difficulty level by slowing their speed or not maneuvering. Other examples of simulation application's ALEs may include, e.g.,

(1) Visual cueing to prompt the student's attention to critical events, such as aircraft maneuvers or failing to initiate needed communication in a timely manner. These ALE cues may be triggered by a player's delays in communicating relevant information, or when a player's biometrics gaze tracking detects an ineffective visual scan.

(2) Audio cueing to reinforce correct player communications which may be triggered when the radio communication meets all the evaluation criteria.

(3) Virtual instructor cueing for incorrect communication cadence or poor radio discipline. This ALE may be triggered by a player's voice biometric detection of a slow or erratic pattern of speech or keying the radio and not speaking in a timely manner, or saying the wrong thing compared to what should have been said according to the evaluation criteria.

(4) Virtual instructor intervention with pausing of the scenario when critical C2 information is missed by the player or inaccurate to the degree it would cause mission failure. An example of this ALE may be if the player incorrectly identified a friendly aircraft as hostile.

In some implementations, a player's performance may be evaluated using speech recognition, which may be performed by taking the audio of the player and interpreting it with, e.g., an appropriate Speech Recognition Grammar Specification (SRGS) file, although other speech recognition models may also be used. This file may specifically outline all possible audible communications a player could make and may enable tutor process 110 to categorize each word, phrase, cadence, tone, etc. as well as the overall communication type. In the C2 serious game simulation use case, the SRGS may include alignment to Air Land Sea Space Application (ALSSA) standards for multi-service tactics, techniques, and procedures for Air Control Communications with the flexibility to modify or extend specifications to adapt to changing needs or operating domains. In some implementations, tutor process 110 may make use of recorded player communication data to train a generative AI model that may be used to interpret and evaluate player communication and replace and/or supplement the use of the SRGS file.

In some implementations, triggering the intervention event may include triggering 316 an agent behavior in the simulation scenario. For instance, in addition to informing and triggering adaptive learning events in real-time game play and providing intelligent tutoring feedback, the game performance data, biometrics, and predictive analytics become powerful tools to drive game agent behaviors and further enhance student learning and performance. In conventional simulations training, deficiencies or gaps in student and player performance are often exposed only randomly when adversary behaviors are exhibited in a way that capitalizes on weaknesses by chance or when noticed and directed by human instructor intervention. Students often only learn to understand and correct their deficiencies when they directly experience failure in this way. However, according to the present disclosure, and in a much more proactive and effective way, tutor process 110 may actively monitor, predict, and identify student deficiencies and errors, and then trigger adversary intelligent agent behaviors precisely to exploit and expose weaknesses any time they are exhibited. The degree to which a student's weaknesses are challenged is also varied based on experience and skill level to maintain the individual within the zone of proximal development.

For example, a player may have a consistent performance weakness that causes the mobility of their visual scan to be consistently stagnant on a specific area of the display, or during a particular phase of play or operations that creates the conditions for the player to fail to react effectively to changes in game entity behaviors. In the tactical intercept use case, these deficiencies may manifest themselves in the form of late recognition and response to critical actions exhibited by any game entity including friendly, unknown, or hostile aircraft. During conventional intercept training, whether simulated or performed with live aircraft, these performance gaps would only be exposed when participants randomly exhibited behaviors that happened to take advantage of and expose a weakness. On the other hand, with the present disclosure, tutor process 110 may identify underlying deficiencies in player behavior through real-time or predictive data analysis, and then trigger the following example and non-limiting interventions:

(1) Any combination of visual, aural, or voice cues prompts to the player making them aware of their performance deficiency.

(2) Any combination of visual, aural, or voice instruction prompts and guidance information that actively assists the player in modifying their performance to correct the deficiency.

(3) Changes in the behavior of game entities specifically to exploit a player performance deficiency.

(4) Real-time and debrief feedback to enhance insight development, learning, and performance improvement.

In some implementations, tutor process 110 may use a variation in intelligent tutor adapting learning approaches that modifies the relationship or uses varied combinations between the separate or integrated use of rules-based algorithms and AI predictions to trigger and drive adaptive learning events. In the example case of tactical intercept training, suppose tutor process 110 identifies that an individual consistently demonstrates slow recognition of adversary behavior changes during a specific phase of the intercept. In play using the simulation, tutor process 110 may initiate triggers of adaptive learning events that target and expose identified weaknesses, including, e.g., initiating adversary maneuvers precisely at the moment the player's performance is most susceptible to the changes. For example, during a tactical intercept, tutor process 110 may detect gaze stagnation on a single target and, based on one or more of the system rules, triggers an adversary maneuver precisely when the player fails to monitor the other target(s), or tutor process 110 may identify delays in communicating critical updates and trigger rapid altitude changes, forcing the player to prioritize communications. These events enable the player to rapidly identify, develop learning insights, and correct learning and performance deficiencies in ways that are simply not possible through conventional training and simulation methods.

In some implementations, the adaptive threat behaviors may also be based on a hybrid set of rules and AI predictions that will adapt to players over time. Because they are based partially on individual attributes like, e.g., currency, experience, qualifications, performance history, etc. they may be tailored to each player. Adaptive threat behaviors will be substantially impacted by player performance deficiencies such as poor situational awareness or decision making. For example, if the game recognizes that the player has not noticed a maneuvering threat group and alerted a blue fighter, adaptive threat behaviors may be triggered to cause the adversaries to turn hot and engage unsuspecting blue fighters. As another example in an emergency management scenario, if an on-scene commander was distracted by another incident and failed to act on observed smoke and threat of fire, adaptive behaviors may be triggered to create an explosion or conflagration that would highlight the players deficiency and help to show them the consequences of such a mistake. It will be appreciated that other adaptive behaviors may be triggered without departing from the scope of the present disclosure.

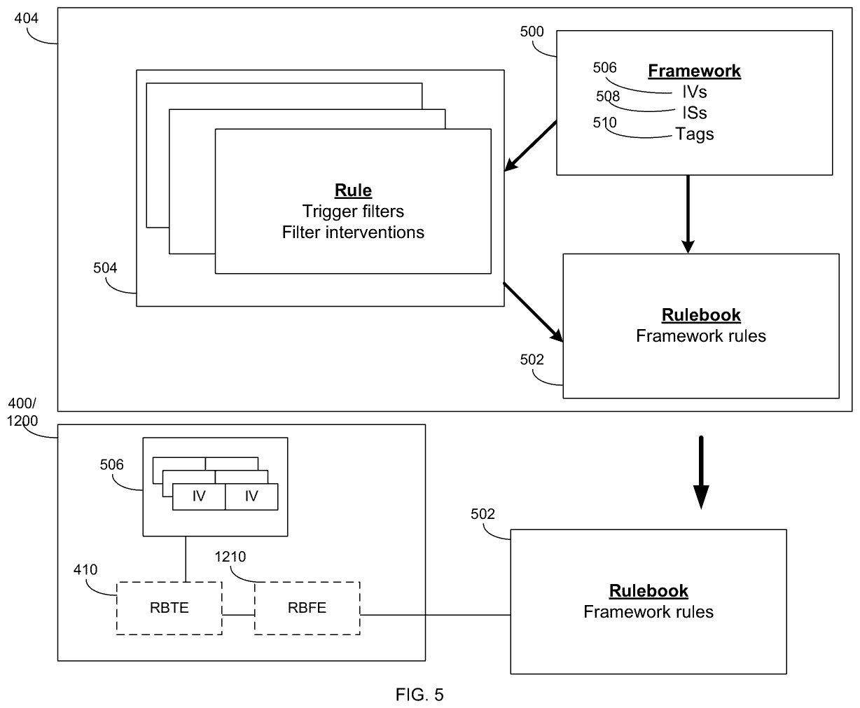

In some implementations, RAI 404 may be part of tutor process 110, or may be a separate application that enables (e.g., via tutor process 110) instructional designers to create and manage RBTE computations. RAI 404 UI may enable developers to interact with each RBTE component model for easier interfacing. For instance, and referring at least to the example implementation of FIG. 5, an example diagrammatic view of components of RAI 404 is shown.

(1) Framework 500. The framework may establish the base structure to process understanding of the above-noted input data variables, interventions, and tags simulation system 400 and/or client electronic device 138 may use to facilitate the desired play and learning outcomes. The simulation framework is unique and may use a distinct object list (or other structure) created in the RAI, such as:
(a) Independent Variables (IVs), which may be parameters in the game that are monitored by tutor process 110. IVs, such as IVs 506, may be either raw data or feature engineered by simulation system 400 to provide more insight. Examples of IVs may include, e.g.:
   (i) Last mission played
   (ii) Last mission score
   (iii) Average score
   (iv) Eye gaze distance to blue air/friendly aircraft entities
   (v) Voice communication pace of speech
(b) Intervention Structures (ISs), such as ISs 508, may be structures for ALEs, which may include an Intervention Name, as well as desired options and values for triggering and/or executing the intervention event. This provides course authors the ability to create vast number of unique ALE interventions, and more directly control how tutor process 110 interacts with the student or player in the simulation. Examples of ISs may include, e.g.:
   (i) Intervention-Warn Student of upcoming communications call
   (ii) Options:
      1. Highlight entity of interest (Example: Blue Air)
         i. Values:
         1. True
         2. False
      2. Highlight area of interest (Example: Designated “Bullseye” point)
         i. Values:
         1. True
         2. False
      3. Pause Game
         i. Values:
         1. True
         2. False
      4. Set Text Warning Color
         i. Values:
         1. Red
         2. Green
         3. Yellow
   (iii) Tags, such as tags 510, may be described as strings that group together IVs to allow grouping and prevent repetition when writing course software. IVs are given tags on IV creation to perform grouping. Examples of tags 510 may include, e.g.:
      a. Eye Distance-IVs tagged-Gaze Distance to bullseye, Gaze Distance to Blue Air, Gaze Distance to Red Air
      b. Pupillometry-IVs tagged-Current Pupil size, Average Pupil size over scenario, Average Pupil size past 5 seconds (or other interval)

(2). Rulebook 502—A rulebook may contain the framework rules that work within, as well as list (or other structure) of rule definitions for an application. Such rules may be derived from policy, regulations, doctrine, or some other form of scenario guidance which may serve to help define bounding conditions or triggers for simulation behaviors. Rules may also be used to establish bounding conditions for AI predictions or prescriptive triggers to ensure simulated behaviors are maintained within reasonable and realistic parameters for the scenario domain. In some implementations, RAI 404 may export one or more rulebooks stored in the rulebook repository, that may be used by RBTE 410 of simulation system 400.

(3) Rule 504—Rules may be generally described as a list of filtered triggers that when all the parameters are met, initiate or “fire” (trigger, execute, etc.) an intervention (ALE). A list of filtered interventions matching the appropriate simulation parameters of the input data may determine which specific intervention should be fired.

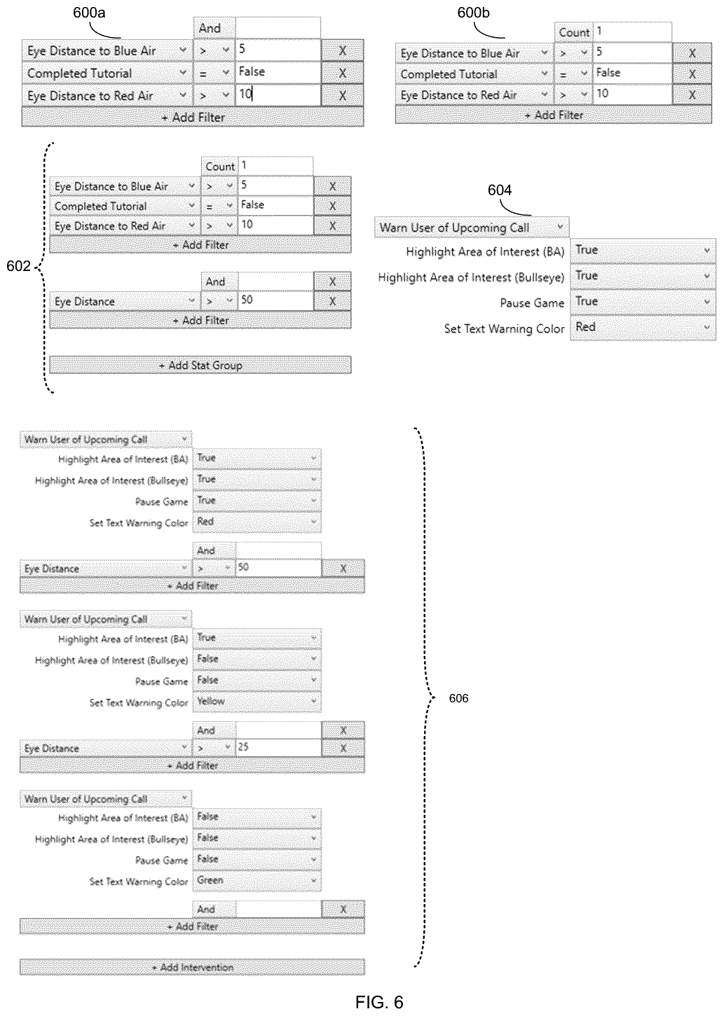

Referring at least to the example implementation of FIG. 6, example options for triggers are shown. For instance, one option is shown as an example filter trigger 600a and 600b.

Filter triggers may be queries used by tutor process 110 to look for specified parameters in the currently running simulation scenario, whether established by the above-noted pre-established rules or the above-noted AI predictions, and if specified parameters are met, tutor process 110 may trigger one or more interventions. Authors may filter using IVs, Tags, or the triggering of other rules. In some implementations, filter triggers may either require all filters to be true (as shown in 600a to match) or only some of the triggers need to be true (as shown in 600b where one of the values must be true to match).

Another example option is shown as example trigger groups 602.

Trigger Groups used by tutor process 110 to expand the filtering options. Each filter group may be an outside AND operator.

Another example option is shown as example intervention 604.

Interventions are Intervention Structures (ISs) with selected options. Multiple different interventions may be implemented using the same IS, as shown in intervention 604.

Another example option is shown as example filter intervention 606.

Filter interventions allow one rule to have multiple possible intervention possibilities. On the rule intervention, tutor process 110 may enable an author to add filters that need to be true to fire (i.e., trigger) the intervention. If the filters are not true, then the rule will proceed through the list (or other structure) looking for the next intervention criteria to determine if the triggering criteria is met.

As an example, use case, assume for example purposes only that students who are learning C2 operations for the first time are using simulation system 400 to learn and become proficient in communications and their scan pattern during their initial qualification training (IQT) in several example and non-limiting ways:

(1) Upon completion of classroom instruction in standardized communications, students may use simulation system 400 beginner level scenarios to reinforce what they have just learned and get repetitions during self-guided play. This allows students to quickly get practical, repetitive practice and build self-confidence through short duration scenarios. Instructors can monitor student progress through the cloud-based replay tool and can address any deficiencies prior to graded events.

(2) Simulation system 400 may replace costly legacy simulator events that are focused solely on basic skills. It is often the case that blocks of training that require legacy simulators for graded events need to be scheduled over the course of multiple weeks due to limited simulator scheduling ability. With simulation system 400 kits, these graded events may be done in a matter of hours and do not necessarily need an instructor present.

(3) In order to maximize student throughput during time limited IQT courses, skill progression must occur rapidly and there is no time to go back and reinforce skills learned earlier in training. Simulation system 400 is able to provide continued proficiency training outside of classroom hours so students may practice basic communications skills.

Human performance biometrics, including voice, eye gaze, pupillometry, etc. may be used by the Tutor process 110 to maximize virtual coaching for IQT students and allow for instant evaluation and correction of deficiencies that are common to first time users of standardized C2 communications. The biometric and gameplay data is stored for ingestion by, e.g., machine learning algorithms (e.g., via MLBAM 406) to train the AI with the ability to determine the capability and performance level of the student and adjust the level of intervention provided by tutor process 110.

In some implementations, simulation system 400 may also be used to perform aptitude testing for individuals considering a career in C2 management. The individual may be offered simple scenarios to manage and tutor process 110 may be used to identify human performance behaviors and attributes that are indicated of success in the field. This aptitude test may be delivered through a wide range of techniques, such as those described throughout, and may be used with or without one or more biometric monitoring (e.g., eye tracking features).

It will be appreciated after reading the present disclosure that alternative computing form factors may be used for client-based applications including, e.g., laptops, tablets, smart phones, mini-computers, desktop computers or other client electronic devices with sufficient processing capability.

As discussed above and referring also at least to the example implementations of FIGS. 3-12, tutor process 110 may receive 302 input data from a user participating in a simulation scenario. Tutor process 110 may receive 304 input data from the simulation scenario. Tutor process 110 may trigger 310 an intervention event in the simulation scenario based upon, at least in part, the input data from the user participating in the simulation scenario and the input data from the simulation scenario.

In some implementations, tutor process 110 may receive 302 input data from a user participating in the simulation scenario. For instance, in some implementations, the input data (e.g., I/O request 115) from the user participating in the simulation scenario may include user biometrics (e.g., gaze tracking, gaze association with objects, entities, and dwell time, pupillometry, voice parameters, heart rate, respiration rate, brain activity, or other parameters), user performance data (e.g., experience level, performance history, currency of performance and training, UI input actions, communications calls and other performance measures, etc.).

In some implementations, tutor process 110 may receive 304 input data from the simulation scenario. For instance, in some implementations, the input data (e.g., I/O request 115) from the simulation scenario may include game state data (e.g., defining scenarios, start and ending conditions, game entities, entity behaviors, event data or other game data). In some implementations, input data from the user or the simulation scenario may be received and stored in memory or other storage device type for access and/or analysis.

In some implementations, tutor process 110 may analyze the input data from the user participating in the simulation scenario and the input data from the simulation scenario, and in some implementations, tutor process 110 may provide feedback to the user participating in the simulation scenario based upon, at least in part, analyzing the input data from the user participating in the simulation scenario and the input data from the simulation scenario. For instance, tutor process 110 may take the input from simulation system 400 such as game events, aircraft group positions, player performance, and human performance biometrics information, including, e.g., eye tracking, to provide to both feature engineering module 408 and RBTE 410 module. Feature engineering module 408 (e.g., via tutor process 110) may perform programmed engineering (as discussed above) on the provided inputs and then send the results to MLBAM 406 to make (e.g., via tutor process 110) predictions about player performance, which may then be sent to RBTE 410. LRS 412 (e.g., via tutor process 110) may send previous (historical) data, as well as new outputs of RBTE 410. In some implementations, players may receive feedback during play in real-time, as well as during post run debriefs.

In some implementations, providing feedback to the user participating in the simulation scenario may include triggering 310 an intervention event in the simulation scenario based upon, at least in part the input data from the user participating in the simulation scenario and the input data from the simulation scenario. For example, as will be discussed in greater detail below, RBTE 410 may (e.g., via tutor process 110) process the above-noted data inputs and monitor play to identify event parameters that call for initiation of appropriate intervention events, also referred to herein as Adaptive Learning Events (ALE). When RBTE 410 (e.g., via tutor process 110) identifies a trigger for a particular ALE, tutor process 110 may command an ALE to fire (trigger) in the simulation running on client electronic device 138.

In some implementations, tutor process 110 may predict 318 performance of the user in the simulation scenario to generate a predicted performance of the user, and in some implementations, predicting performance of the user in the simulation scenario to generate the predicted performance of the user may include processing 320, using a trained predictive model, the input data from the user participating in the simulation scenario and the input data from the simulation scenario processed using a feature engineering model. For instance, MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBTE 410. In some implementations, processed data may include game state and event data, player performance data, and human performance biometrics data, etc. At the heart of MLBAM 406 is a predictive model (e.g., of tutor process 110) that may be pre-trained on historical performance data (e.g., user input data and/or simulation scenario input data) to recognize player patterns and deviations from the new, real-time input data of the currently running simulation. In some implementations, the training data may include the example and non-limiting variables discussed above.

Generally, the pre-trained model may serve as MLBAM 406 decision making entity. MLBAM 406 predictions may be relayed (e.g., via an output interface) to RBTE 410 where they may be processed by tutor process 110 with additional rules-based algorithms and evaluated as potential ALE triggers. Generally, the pre-trained model may serve as MLBAM 406 decision making entity. MLBAM 406 predictions may be relayed (e.g., via an output interface) to RBTE 410 where they may be processed by tutor process 110 with additional rules-based algorithms and evaluated as potential ALE triggers. One such example is the use of voice cadence to determine whether the player is speaking too fast or too slow. The simulation records spoken words-per-minute (WPM) as an Independent Variable and compares that value to a rule that provides a lower and upper WPM limit. If the WPM IV is above or below the rule's value, then an ALE is triggered that tells the player to “watch their comm cadence.”

In some implementations, triggering the intervention event may include at least one of adjusting 312 a difficulty level of the simulation scenario. For example, ALEs may be used to help keep the player in the zone of proximal development and adapt to their skill level and learning needs, so they will improve at the optimum rate. When a student is being challenged at a high level, ALEs may be triggered that will provide assistance or implement subtle changes in play that reduce difficulty level. Conversely, ALEs may be initiated during play to make scenarios more challenging for a high performing student or player so they will be pushed to develop higher level skills more quickly. In some implementations, triggering the intervention event may include providing at least one of a visual cue, an audio cue, a virtual instructor cue, and a virtual instructor intervention. For instance, a few examples of simulation application's ALEs may include, e.g.:

(1) Visual cueing to prompt the student's attention to critical events, such as aircraft maneuvers or failing to initiate needed communication in a timely manner. These ALE cues may be triggered by a player's delays in communicating relevant information, or when a player's biometrics gaze tracking detects an ineffective visual scan.

(2) Audio cueing to reinforce correct player communications which may be triggered when the radio communication meets all the evaluation criteria.

(3) Virtual instructor cueing for incorrect communication cadence or poor radio discipline. This ALE may be triggered by a player's voice biometric detection of a slow or erratic pattern of speech or keying the radio and not speaking in a timely manner, or saying the wrong thing compared to what should have been said according to the evaluation criteria.

(4) Virtual instructor intervention with pausing of the scenario when critical C2 information is missed by the player or inaccurate to the degree it would cause mission failure. An example of this ALE may be if the player incorrectly identified a friendly aircraft as hostile.

In some implementations, a player's performance may be evaluated using speech recognition, which may be performed by taking the audio of the player and interpreting it with, e.g., an appropriate Speech Recognition Grammar Specification (SRGS) file, although other speech recognition models may also be used. This file may specifically outline all possible audible communications a player could make and may enable tutor process 110 to categorize each word, phrase, cadence, tone, etc. as well as the overall communication type. In the C2 serious game simulation use case, the SRGS may include alignment to Air Land Sea Space Application (ALSSA) standards for multi-service tactics, techniques, and procedures for Air Control Communications with the flexibility to modify or extend specifications to adapt to changing needs or operating domains. In some implementations, tutor process 110 may make use of recorded player communication data to train a generative AI model that may be used to interpret and evaluate player communication and replace and/or supplement the use of the SRGS file.

In some implementations, triggering the intervention event may include triggering 316 an agent behavior in the simulation scenario. For instance, in addition to informing and triggering adaptive learning events in real-time game play and providing intelligent tutoring feedback, the game performance data, biometrics, and predictive analytics become powerful tools to drive game agent behaviors and further enhance student learning and performance. In conventional simulations training, deficiencies or gaps in student and player performance are often exposed only randomly when adversary behaviors are exhibited in a way that capitalizes on weaknesses by chance or when noticed and directed by human instructor intervention. Students often only learn to understand and correct their deficiencies when they directly experience failure in this way. However, according to the present disclosure, and in a much more proactive and effective way, tutor process 110 may actively monitor, predict, and identify student deficiencies and errors, and then trigger adversary intelligent agent behaviors precisely to exploit and expose weaknesses any time they are exhibited. The degree to which a student's weaknesses are challenged is also varied based on experience and skill level to maintain the individual within the zone of proximal development.

For example, a player may have a consistent performance weakness that causes the mobility of their visual scan to be consistently stagnant on a specific area of the display, or during a particular phase of play or operations that creates the conditions for the player to fail to react effectively to changes in game entity behaviors. In the tactical intercept use case, these deficiencies may manifest themselves in the form of late recognition and response to critical actions exhibited by any game entity including friendly, unknown, or hostile aircraft. During conventional intercept training, whether simulated or performed with live aircraft, these performance gaps would only be exposed when participants randomly exhibited behaviors that happened to take advantage of and expose a weakness. On the other hand, with the present disclosure, tutor process 110 may identify underlying deficiencies in player behavior through real-time or predictive data analysis, and then trigger the following example and non-limiting interventions:

(1) Any combination of visual, aural, or voice cues prompts to the player making them aware of their performance deficiency. (2) Any combination of visual, aural, or voice instruction prompts and guidance information that actively assists the player in modifying their performance to correct the deficiency. (3) Changes in the behavior of game entities specifically to exploit a player performance deficiency. (4) Real-time and debrief feedback to enhance insight development, learning, and performance improvement.

In some implementations, tutor process 110 may use a variation in intelligent tutor adapting learning approaches that modifies the relationship or uses varied combinations between the separate or integrated use of rules-based algorithms and AI predictions to trigger and drive adaptive learning events. In the example case of tactical intercept training, suppose tutor process 110 identifies that an individual consistently demonstrates slow recognition of adversary behavior changes during a specific phase of the intercept. In play using the simulation, tutor process 110 may initiate triggers of adaptive learning events that target and expose identified weaknesses, including, e.g., initiating adversary maneuvers precisely at the moment the player's performance is most susceptible to the changes, as discussed above. These events enable the player to rapidly identify, develop learning insights, and correct learning and performance deficiencies in ways that are simply not possible through conventional training and simulation methods.

In some implementations, the adaptive threat behaviors may also be based on a hybrid set of rules and AI predictions that will adapt to players over time. Because they are based partially on individual attributes like, e.g., currency, experience, qualifications, performance history, etc. they may be tailored to each player. Adaptive threat behaviors will be substantially impacted by player performance deficiencies such as poor situational awareness or decision making. For example, if the game recognizes that the player has not noticed a maneuvering threat group and alerted a blue fighter, adaptive threat behaviors may be triggered to cause the adversaries to turn hot and engage unsuspecting blue fighters. As another example in an emergency management scenario, if an on-scene commander was distracted by another incident and failed to act on observed smoke and threat of fire, adaptive behaviors may be triggered to create an explosion or conflagration that would highlight the players deficiency and help to show them the consequences of such a mistake. It will be appreciated that other adaptive behaviors may be triggered without departing from the scope of the present disclosure.

In some implementations, RAI 404 may be part of tutor process 110, or may be a separate application that enables (e.g., via tutor process 110) instructional designers to create and manage RBTE computations. RAI 404 UI may enable developers to interact with each RBTE component model for easier interfacing. For instance, and referring at least to the example implementation of FIG. 5, an example diagrammatic view of components of RAI 404 is shown.

(1) Framework 500. In some implementations, tutor process 110 may monitor 322 the simulation scenario for one of a predicted performance of the user, the input data from the user participating in the simulation scenario, and the input data from the simulation scenario. For example, the framework may establish the base structure to process understanding of the above-noted input data variables, interventions, and tags simulation system 400 and/or client electronic device 138 may use to facilitate the desired play and learning outcomes. The simulation framework is unique and may use a distinct object list (or other structure) created in the RAI, such as:
(a) Independent Variables (IVs), which may be parameters in the game that are monitored by tutor process 110. IVs, such as IVs 506, may be either raw data or feature engineered by simulation system 400 to provide more insight. Examples of IVs may include those described above; (b) Intervention Structures (ISs), such as ISs 508, may be structures for ALEs, which may include an Intervention Name, as well as desired options and values for triggering and/or executing the intervention event. This provides course authors the ability to create vast number of unique ALE interventions, and more directly control how tutor process 110 interacts with the student or player in the simulation. Examples of ISs may include those described above.
(iii) Tags, such as tags 510, may be described as strings that group together IVs to allow grouping and prevent repetition when writing course software. IVs are given tags on IV creation to perform grouping. Examples of tags 510 may include those described above.

(2). Rulebook 502—A rulebook may contain the framework rules that work within, as well as list (or other structure) of rule definitions for an application. Such rules may be derived from policy, regulations, doctrine, or some other form of scenario guidance which may serve to help define bounding conditions or triggers for simulation behaviors. Rules may also be used to establish bounding conditions for AI predictions or prescriptive triggers to ensure simulated behaviors are maintained within reasonable and realistic parameters for the scenario domain. In some implementations, RAI 404 may export one or more rulebooks stored in the rulebook repository, that may be used by RBTE 410 of simulation system 400.

(3) Rule 504—Rules may be generally described as a list of filtered triggers that when all the parameters are met, initiate or “fire” (trigger, execute, etc.) an intervention (ALE). A list of filtered interventions matching the appropriate simulation parameters of the input data may determine which specific intervention should be fired.

Referring at least to the example implementation of FIG. 6, example options for triggers are shown. For instance, one option is shown as an example filter trigger 600a and 600b.

In some implementations, tutor process 110 may match 324 one of the predicted performance of the user, the input data from the user participating in the simulation scenario, and the input data from the simulation scenario to a rule of a plurality of rules. For instance, filter triggers may be queries used by tutor process 110 to look for specified parameters in the currently running simulation scenario, whether established by the above-noted pre-established rules or the above-noted AI predictions, and if specified parameters are met, tutor process 110 may trigger one or more interventions that match. Authors may filter using IVs, Tags, or the triggering of other rules. In some implementations, filter triggers may either require all filters to be true (as shown in 600a to match) or only some of the triggers need to be true (as shown in 600b where one of the values must be true to match).

Another example option is shown as example trigger groups 602.

Trigger Groups used by tutor process 110 to expand the filtering options. Each filter group may be an outside AND operator.

Another example option is shown as example intervention 604.

Interventions are Intervention Structures (ISs) with selected options. Multiple different interventions may be implemented using the same IS, as shown in intervention 604.

Another example option is shown as example filter intervention 606.

Filter interventions allow one rule to have multiple possible intervention possibilities. On the rule intervention, tutor process 110 may enable an author to add filters that need to be true to fire (i.e., trigger) the intervention. If the filters are not true, then the rule will proceed through the list (or other structure) looking for the next intervention criteria to determine if the triggering criteria is met.

Generally, organizations typically have continuing education requirements to ensure that their personnel maintain adequate proficiency to successfully perform their duties. This continuing education is often time based, meaning if an operator/user does not conduct a minimum requirement of C2 operations within a certain time period, they may need refresher training or potentially full requalification training if the absence is over an extended period. In some implementations, simulation application 120 (e.g., via tutor process 110) may provide access to the necessary continuing education training with significant reduced time and resources required compared to legacy method and infrastructure. This allows operational units to maintain work force proficiency in less time and with fewer human and training infrastructure resources needed.

As an example, simulation application 120 (e.g., via tutor process 110) may be used by the Air National Guard to requalify one of their Weapons Directors after missing several months of work following the birth of her child. In the example, she would be able to quickly requalify and return to duty in a matter of hours after demonstrating proficiency in several simulation application 120 tactical intercept scenarios.

As discussed above and referring also at least to the example implementations of FIGS. 3-12, tutor process 110 may receive 302 input data from a user participating in a simulation scenario. Tutor process 110 may receive 304 input data from the simulation scenario, wherein the input data from the user participating in the simulation scenario and the input data from the simulation scenario may be processed using feature engineering data. Tutor process 110 may predict 318 performance of the user in the simulation scenario to generate a predicted performance of the user based upon, at least in part, the input data from the user participating in the simulation scenario and the input data from the simulation scenario processed using the artificial intelligence feature engineering model.

In some implementations, tutor process 110 may receive 302 input data from a user participating in the simulation scenario. For instance, in some implementations, the input data (e.g., I/O request 115) from the user participating in the simulation scenario may include user biometrics (e.g., gaze tracking, gaze association with objects, entities, and dwell time, pupillometry, voice parameters, heart rate, respiration rate, brain activity, or other parameters), user performance data (e.g., experience level, performance history, currency of performance and training, UI input actions, communications calls and other performance measures, etc.).

In some implementations, tutor process 110 may receive 304 input data from the simulation scenario, wherein the input data from the user participating in the simulation scenario and the input data from the simulation scenario may be processed using feature engineering data. For instance, in some implementations, the input data (e.g., I/O request 115) from the simulation scenario may include game state data (e.g., defining scenarios, start and ending conditions, game entities, entity behaviors, event data or other game data). In some implementations, input data from the user or the simulation scenario may be received and stored in memory or other storage device type for access and/or analysis.

In some implementations, tutor process 110 may analyze the input data from the user participating in the simulation scenario and the input data from the simulation scenario, and in some implementations, tutor process 110 may provide feedback to the user participating in the simulation scenario based upon, at least in part, analyzing the input data from the user participating in the simulation scenario and the input data from the simulation scenario. For instance, tutor process 110 may take the input from simulation system 400 such as game events, aircraft group positions, player performance, and human performance biometrics information, including, e.g., eye tracking, to provide to both feature engineering module 408 and RBTE 410 module. Feature engineering module 408 (e.g., via tutor process 110) may perform programmed engineering (as discussed above) on the provided inputs and then send the results to MLBAM 406 to make (e.g., via tutor process 110) predictions about player performance, which may then be sent to RBTE 410. LRS 412 (e.g., via tutor process 110) may send previous (historical) data, as well as new outputs of RBTE 410. In some implementations, players may receive feedback during play in real-time, as well as during post run debriefs.

In some implementations, providing feedback to the user participating in the simulation scenario may include triggering an intervention event in the simulation scenario based upon, at least in part the input data from the user participating in the simulation scenario and the input data from the simulation scenario. For example, as will be discussed in greater detail below, RBTE 410 may (e.g., via tutor process 110) process the above-noted data inputs and monitor play to identify event parameters that call for initiation of appropriate intervention events, also referred to herein as Adaptive Learning Events (ALE). When RBTE 410 (e.g., via tutor process 110) identifies a trigger for a particular ALE, tutor process 110 may command an ALE to fire (trigger) in the simulation running on client electronic device 138.

In some implementations, tutor process 110 may predict 318 performance of the user in the simulation scenario to generate a predicted performance of the user, and in some implementations, predicting performance of the user in the simulation scenario to generate the predicted performance of the user may include processing 320, using a trained predictive model, the input data from the user participating in the simulation scenario and the input data from the simulation scenario processed using feature engineering data. For instance, MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBTE 410. In some implementations, processed data may include game state and event data, player performance data, and human performance biometrics data, etc. In some implementations, training data for the trained predictive model may include independent variables, and wherein the independent variables may include at least one of user biometrics, user performance data, game state data, historical user biometrics, historical user performance data, and historical game state data. For instance, at the heart of MLBAM 406 is a predictive model (e.g., of tutor process 110) that may be pre-trained on historical performance data (e.g., user input data and/or simulation scenario input data) to recognize player patterns and deviations from the new, real-time input data of the currently running simulation. In some implementations, the training data may include the following example and non-limiting variables:

1. Independent Variables (IV) such as:
(a) Game state data defining scenarios, start and ending conditions, game entities, entity behaviors, event data or other game data.
(b) Player performance data including experience level, performance history, currency of performance and training, UI input actions, communications calls and other performance measures.
(c) Player human performance biometrics including gaze tracking, gaze association with entities and dwell time, pupillometry, voice parameters, and potentially heart rate, respiration rate, brain activity or other physiology parameters being monitored in response to stimulus and/or stressors of game play.

In some implementations, the above-noted training data for the trained predictive model may include dependent variables, and in some implementations, the dependent variables may include at least one of communication performance of the simulation scenario and event outcomes of the simulation scenario. For example:

2. Dependent or Predictor Variables including:
(a) Measures of communication performance and effectiveness such as timeliness, accuracy, completeness, and adherence to standards or other measures.
(b) Measures of event or mission outcomes.

Generally, the pre-trained model may serve as MLBAM 406 decision making entity. MLBAM 406 predictions may be relayed (e.g., via an output interface) to RBTE 410 where they may be processed by tutor process 110 with additional rules-based algorithms and evaluated as potential ALE triggers, as discussed above.

In some implementations, triggering the intervention event may include at least one of adjusting 312 a difficulty level of the simulation scenario, as discussed above. For example, ALEs may be used to help keep the player in the zone of proximal development and adapt to their skill level and learning needs, so they will improve at the optimum rate. When a student is being challenged at a high level, ALEs may be triggered that will provide assistance or implement subtle changes in play that reduce difficulty level. Conversely, ALEs may be initiated during play to make scenarios more challenging for a high performing student or player so they will be pushed to develop higher level skills more quickly. In some implementations, triggering the intervention event may include providing at least one of a visual cue, an audio cue, a virtual instructor cue, and a virtual instructor intervention. For instance, a few examples of simulation application's ALEs may include, e.g.:

(1) Visual cueing to prompt the student's attention to critical events, such as aircraft maneuvers or failing to initiate needed communication in a timely manner. These ALE cues may be triggered by a player's delays in communicating relevant information, or when a player's biometrics gaze tracking detects an ineffective visual scan.

(2) Audio cueing to reinforce correct player communications which may be triggered when the radio communication meets all the evaluation criteria.

(3) Virtual instructor cueing for incorrect communication cadence or poor radio discipline. This ALE may be triggered by a player's voice biometric detection of a slow or erratic pattern of speech or keying the radio and not speaking in a timely manner, or saying the wrong thing compared to what should have been said according to the evaluation criteria.

(4) Virtual instructor intervention with pausing of the scenario when critical C2 information is missed by the player or inaccurate to the degree it would cause mission failure. An example of this ALE may be if the player incorrectly identified a friendly aircraft as hostile.

In some implementations, a player's performance may be evaluated using speech recognition, which may be performed by taking the audio of the player and interpreting it with, e.g., an appropriate Speech Recognition Grammar Specification (SRGS) file, although other speech recognition models may also be used. This file may specifically outline all possible audible communications a player could make and may enable tutor process 110 to categorize each word, phrase, cadence, tone, etc. as well as the overall communication type. In the C2 serious game simulation use case, the SRGS may include alignment to Air Land Sea Space Application (ALSSA) standards for multi-service tactics, techniques, and procedures for Air Control Communications with the flexibility to modify or extend specifications to adapt to changing needs or operating domains. In some implementations, tutor process 110 may make use of recorded player communication data to train a generative AI model that may be used to interpret and evaluate player communication and replace and/or supplement the use of the SRGS file.

In some implementations, triggering the intervention event may include triggering 316 an agent behavior in the simulation scenario. For instance, in addition to informing and triggering adaptive learning events in real-time game play and providing intelligent tutoring feedback, the game performance data, biometrics, and predictive analytics become powerful tools to drive game agent behaviors and further enhance student learning and performance. In conventional simulations training, deficiencies or gaps in student and player performance are often exposed only randomly when adversary behaviors are exhibited in a way that capitalizes on weaknesses by chance or when noticed and directed by human instructor intervention. Students often only learn to understand and correct their deficiencies when they directly experience failure in this way. However, according to the present disclosure, and in a much more proactive and effective way, tutor process 110 may actively monitor, predict, and identify student deficiencies and errors, and then trigger adversary intelligent agent behaviors precisely to exploit and expose weaknesses any time they are exhibited. The degree to which a student's weaknesses are challenged is also varied based on experience and skill level to maintain the individual within the zone of proximal development.

For example, a player may have a consistent performance weakness that causes the mobility of their visual scan to be consistently stagnant on a specific area of the display, or during a particular phase of play or operations that creates the conditions for the player to fail to react effectively to changes in game entity behaviors. In the tactical intercept use case, these deficiencies may manifest themselves in the form of late recognition and response to critical actions exhibited by any game entity including friendly, unknown, or hostile aircraft. During conventional intercept training, whether simulated or performed with live aircraft, these performance gaps would only be exposed when participants randomly exhibited behaviors that happened to take advantage of and expose a weakness. On the other hand, with the present disclosure, tutor process 110 may identify underlying deficiencies in player behavior through real-time or predictive data analysis, and then trigger the following example and non-limiting interventions:

(1) Any combination of visual, aural, or voice cues prompts to the player making them aware of their performance deficiency.

(2) Any combination of visual, aural, or voice instruction prompts and guidance information that actively assists the player in modifying their performance to correct the deficiency.

(3) Changes in the behavior of game entities specifically to exploit a player performance deficiency.

(4) Real-time and debrief feedback to enhance insight development, learning, and performance improvement.

In some implementations, tutor process 110 may use a variation in intelligent tutor adapting learning approaches that modifies the relationship or uses varied combinations between the separate or integrated use of rules-based algorithms and AI predictions to trigger and drive adaptive learning events. In the example case of tactical intercept training, suppose tutor process 110 identifies that an individual consistently demonstrates slow recognition of adversary behavior changes during a specific phase of the intercept. In play using the simulation, tutor process 110 may initiate triggers of adaptive learning events that target and expose identified weaknesses, including, e.g., initiating adversary maneuvers precisely at the moment the player's performance is most susceptible to the changes, as discussed above. These events enable the player to rapidly identify, develop learning insights, and correct learning and performance deficiencies in ways that are simply not possible through conventional training and simulation methods.

In some implementations, the adaptive threat behaviors may also be based on a hybrid set of rules and AI predictions that will adapt to players over time. Because they are based partially on individual attributes like, e.g., currency, experience, qualifications, performance history, etc. they may be tailored to each player. Adaptive threat behaviors will be substantially impacted by player performance deficiencies such as poor situational awareness or decision making. For example, if the game recognizes that the player has not noticed a maneuvering threat group and alerted a blue fighter, adaptive threat behaviors may be triggered to cause the adversaries to turn hot and engage unsuspecting blue fighters. As another example in an emergency management scenario, if an on-scene commander was distracted by another incident and failed to act on observed smoke and threat of fire, adaptive behaviors may be triggered to create an explosion or conflagration that would highlight the players deficiency and help to show them the consequences of such a mistake. It will be appreciated that other adaptive behaviors may be triggered without departing from the scope of the present disclosure.

In some implementations, RAI 404 may be part of tutor process 110, or may be a separate application that enables (e.g., via tutor process 110) instructional designers to create and manage RBTE computations. RAI 404 UI may enable developers to interact with each RBTE component model for easier interfacing. For instance, and referring at least to the example implementation of FIG. 5, an example diagrammatic view of components of RAI 404 is shown.

(1) Framework 500. In some implementations, tutor process 110 may monitor the simulation scenario for one of a predicted performance of the user, the input data from the user participating in the simulation scenario, and the input data from the simulation scenario. For example, the framework may establish the base structure to process understanding of the above-noted input data variables, interventions, and tags simulation system 400 and/or client electronic device 138 may use to facilitate the desired play and learning outcomes. The simulation framework is unique and may use a distinct object list (or other structure) created in the RAI, such as:
(a) Independent Variables (IVs), which may be parameters in the game that are monitored by tutor process 110. IVs, such as IVs 506, may be either raw data or feature engineered by simulation system 400 to provide more insight. Examples of IVs may include those described above.
(b) Intervention Structures (ISs), such as ISs 508, may be structures for ALEs, which may include an Intervention Name, as well as desired options and values for triggering and/or executing the intervention event. This provides course authors the ability to create vast number of unique ALE interventions, and more directly control how tutor process 110 interacts with the student or player in the simulation. Examples of ISs may include those described above.
(iii) Tags, such as tags 510, may be described as strings that group together IVs to allow grouping and prevent repetition when writing course software. IVs are given tags on IV creation to perform grouping. Examples of tags 510 may include those described above.

(2). Rulebook 502—A rulebook may contain the framework rules that work within, as well as list (or other structure) of rule definitions for an application. Such rules may be derived from policy, regulations, doctrine, or some other form of scenario guidance which may serve to help define bounding conditions or triggers for simulation behaviors. Rules may also be used to establish bounding conditions for AI predictions or prescriptive triggers to ensure simulated behaviors are maintained within reasonable and realistic parameters for the scenario domain. In some implementations, RAI 404 may export one or more rulebooks stored in the rulebook repository, that may be used by RBTE 410 of simulation system 400.

(3) Rule 504—Rules may be generally described as a list of filtered triggers that when all the parameters are met, initiate or “fire” (trigger, execute, etc.) an intervention (ALE). A list of filtered interventions matching the appropriate simulation parameters of the input data may determine which specific intervention should be fired.

Referring at least to the example implementation of FIG. 6, example options for triggers are shown. For instance, one option is shown as an example filter trigger 600a and 600b.

In some implementations, tutor process 110 may match one of the predicted performance of the user, the input data from the user participating in the simulation scenario, and the input data from the simulation scenario to a rule of a plurality of rules. For instance, filter triggers may be queries used by tutor process 110 to look for specified parameters in the currently running simulation scenario, whether established by the above-noted pre-established rules or the above-noted AI predictions, and if specified parameters are met, tutor process 110 may trigger one or more interventions that match. Authors may filter using IVs, Tags, or the triggering of other rules. In some implementations, filter triggers may either require all filters to be true (as shown in 600a to match) or only some of the triggers need to be true (as shown in 600b where one of the values must be true to match).

Another example option is shown as example trigger groups 602.

Trigger Groups used by tutor process 110 to expand the filtering options. Each filter group may be an outside AND operator.

Another example option is shown as example intervention 604.

Interventions are Intervention Structures (ISs) with selected options. Multiple different interventions may be implemented using the same IS, as shown in intervention 604.

Another example option is shown as example filter intervention 606.

Filter interventions allow one rule to have multiple possible intervention possibilities. On the rule intervention, tutor process 110 may enable an author to add filters that need to be true to fire (i.e., trigger) the intervention. If the filters are not true, then the rule will proceed through the list (or other structure) looking for the next intervention criteria to determine if the triggering criteria is met.

It will be appreciated after reading the present disclosure that tutor process 110 (e.g., via simulation application 120 and/or simulation system 400) may be integrated into or otherwise used by any training application, including simulation systems, legacy computer-based training applications, extended reality (XR) based interactive training systems including virtual (VR), mixed, and augmented reality, etc. For example, tutor process 110 may be used to provide virtual coaching to an individual using an augmented reality solution to practice the performance of maintenance inspections or tasks on physical systems such as vehicles, support equipment, facilities, or other infrastructure. In this case, tutor process 110 may sense that the individual is experiencing difficulty performing a step in a task and provide the individual with augmented reality suggestions, cues, prompts, guidance or other forms of intervention and adaptive learning events.

As discussed above and referring also at least to the example implementations of FIGS. 3-12, tutor process 110 may receive 302 input data from a user participating in a simulation scenario. Tutor process 110 may receive 304 input data from the simulation scenario. Tutor process 110 may monitor 322 the simulation scenario for one of a predicted performance of the user, the input data from the user participating in the simulation scenario, and the input data from the simulation scenario. Tutor process 110 may match 324 one of the predicted performance of the user, the input data from the user participating in the simulation scenario, and the input data from the simulation scenario to a rule of a plurality of rules. Tutor process 110 may trigger 310 an intervention event in the simulation scenario based upon, at least in part, matching the one of the predicted performance of the user, the input data from the user participating in the simulation scenario, and the input data from the simulation scenario to the rule of the plurality of rules.

In some implementations, tutor process 110 may receive 302 input data from a user participating in the simulation scenario. For instance, in some implementations, the input data (e.g., I/O request 115) from the user participating in the simulation scenario may include user biometrics (e.g., gaze tracking, gaze association with objects, entities, and dwell time, pupillometry, voice parameters, heart rate, respiration rate, brain activity, or other parameters), user performance data (e.g., experience level, performance history, currency of performance and training, UI input actions, communications calls and other performance measures, etc.).

In some implementations, tutor process 110 may receive 304 input data from the simulation scenario, wherein the input data from the user participating in the simulation scenario and the input data from the simulation scenario may be processed using feature engineering data. For instance, in some implementations, the input data (e.g., I/O request 115) from the simulation scenario may include game state data (e.g., defining scenarios, start and ending conditions, game entities, entity behaviors, event data or other game data). In some implementations, input data from the user or the simulation scenario may be received and stored in memory or other storage device type for access and/or analysis.

In some implementations, tutor process 110 may analyze the input data from the user participating in the simulation scenario and the input data from the simulation scenario, and in some implementations, tutor process 110 may provide feedback to the user participating in the simulation scenario based upon, at least in part, analyzing the input data from the user participating in the simulation scenario and the input data from the simulation scenario. For instance, tutor process 110 may take the input from simulation system 400 such as game events, aircraft group positions, player performance, and human performance biometrics information, including, e.g., eye tracking, to provide to both feature engineering module 408 and RBTE 410 module. Feature engineering module 408 (e.g., via tutor process 110) may perform programmed engineering, as discussed above, on the provided inputs and then send the results to MLBAM 406 to make (e.g., via tutor process 110) predictions about player performance, which may then be sent to RBTE 410. LRS 412 (e.g., via tutor process 110) may send previous (historical) data, as well as new outputs of RBTE 410. In some implementations, players may receive feedback during play in real-time, as well as during post run debriefs.

In some implementations, providing feedback to the user participating in the simulation scenario may include triggering 310 an intervention event in the simulation scenario based upon, at least in part, matching at least one of a predicted performance of the user, the input data from the user participating in the simulation scenario and the input data from the simulation scenario. For example, as will be discussed in greater detail below, RBTE 410 may (e.g., via tutor process 110) process the above-noted data inputs and monitor play to identify event parameters that call for initiation of appropriate intervention events, also referred to herein as Adaptive Learning Events (ALE). When RBTE 410 (e.g., via tutor process 110) identifies a trigger for a particular ALE, tutor process 110 may command an ALE to fire (trigger) in the simulation running on client electronic device 138.

In some implementations, tutor process 110 may predict 318 performance of the user in the simulation scenario to generate a predicted performance of the user, and in some implementations, predicting performance of the user in the simulation scenario to generate the predicted performance of the user may include processing 320, using a trained predictive model, the input data from the user participating in the simulation scenario and the input data from the simulation scenario processed using feature engineering data. For instance, MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBTE 410. In some implementations, processed data may include game state and event data, player performance data, and human performance biometrics data, etc. In some implementations, tutor process 110 may be integrated into larger-scale live, virtual, and constructive (LVC) training architectures, including massive multi-player online game environments, to support distributed mission training across multiple domains and platforms. In these scenarios, tutor process 110 and the enabled NPC entities may be selectively introduced to fill roles where no live participants are available. For example, during an emergency management scenario where a dispatcher trainee is supported by a live police responder but lacks a live fire responder, a tutor process 110 generated NPC can be inserted to fulfill that critical role. By seamlessly incorporating NPCs into the virtual networked environment, tutor process 110 may ensure comprehensive, flexible, and fully resourced training, decoupling performance and readiness objectives from scheduling and personnel availability constraints.

In some implementations, training data for the trained predictive model may include independent variables, and wherein the independent variables may include at least one of user biometrics, user performance data, game state data, historical user biometrics, historical user performance data, and historical game state data. For instance, at the heart of MLBAM 406 is a predictive model (e.g., of tutor process 110) that may be pre-trained on historical performance data (e.g., user input data and/or simulation scenario input data) to recognize player patterns and deviations from the new, real-time input data of the currently running simulation. In some implementations, the training data may include the following example and non-limiting variables:

1. Independent Variables (IV) such as:
(a) Game state data defining scenarios, start and ending conditions, game entities, entity behaviors, event data or other game data. (b) Player performance data including experience level, performance history, currency of performance and training, UI input actions, communications calls and other performance measures. (c) Player human performance biometrics including gaze tracking, gaze association with entities and dwell time, pupillometry, voice parameters, and potentially heart rate, respiration rate, brain activity or other physiology parameters being monitored in response to stimulus and/or stressors of game play.

In some implementations, the above-noted training data for the trained predictive model may include dependent variables, and in some implementations, the dependent variables may include at least one of communication performance of the simulation scenario and event outcomes of the simulation scenario. For example:

2. Dependent or Predictor Variables including: (a) Measures of communication performance and effectiveness such as timeliness, accuracy, completeness, and adherence to standards or other measures. (b) Measures of event or mission outcomes.

Generally, the pre-trained model may serve as MLBAM 406 decision making entity. MLBAM 406 predictions may be relayed (e.g., via an output interface) to RBTE 410 where they may be processed by tutor process 110 with additional rules-based algorithms and evaluated as potential ALE triggers, as discussed above.

In some implementations, triggering the intervention event may include at least one of adjusting 312 a difficulty level of the simulation scenario. For example, ALEs may be used to help keep the player in the zone of proximal development and adapt to their skill level and learning needs, so they will improve at the optimum rate. When a student is being challenged at a high level, ALEs may be triggered that will provide assistance or implement subtle changes in play that reduce difficulty level, as discussed above. Conversely, ALEs may be initiated during play to make scenarios more challenging for a high performing student or player so they will be pushed to develop higher level skills more quickly. In some implementations, triggering the intervention event may include providing 314 at least one of a visual cue, an audio cue, a virtual instructor cue, and a virtual instructor intervention. For instance, a few examples of simulation application's ALEs may include, e.g.: (1) Visual cueing to prompt the student's attention to critical events, such as aircraft maneuvers or failing to initiate needed communication in a timely manner. These ALE cues may be triggered by a player's delays in communicating relevant information, or when a player's biometrics gaze tracking detects an ineffective visual scan. (2) Audio cueing to reinforce correct player communications which may be triggered when the radio communication meets all the evaluation criteria. (3) Virtual instructor cueing for incorrect communication cadence or poor radio discipline. This ALE may be triggered by a player's voice biometric detection of a slow or erratic pattern of speech or keying the radio and not speaking in a timely manner, or saying the wrong thing compared to what should have been said according to the evaluation criteria. (4) Virtual instructor intervention with pausing of the scenario when critical C2 information is missed by the player or inaccurate to the degree it would cause mission failure. An example of this ALE may be if the player incorrectly identified a friendly aircraft as hostile.

In some implementations, a player's performance may be evaluated using speech recognition, which may be performed by taking the audio of the player and interpreting it with, e.g., an appropriate Speech Recognition Grammar Specification (SRGS) file, although other speech recognition models may also be used. This file may specifically outline all possible audible communications a player could make and may enable tutor process 110 to categorize each word, phrase, cadence, tone, etc. as well as the overall communication type. In the C2 serious game simulation use case, the SRGS may include alignment to Air Land Sea Space Application (ALSSA) standards for multi-service tactics, techniques, and procedures for Air Control Communications with the flexibility to modify or extend specifications to adapt to changing needs or operating domains. In some implementations, tutor process 110 may make use of recorded player communication data to train a generative AI model that may be used to interpret and evaluate player communication and replace and/or supplement the use of the SRGS file.

In some implementations, triggering the intervention event may include triggering 316 an agent behavior in the simulation scenario. For instance, in addition to informing and triggering adaptive learning events in real-time game play and providing intelligent tutoring feedback, the game performance data, biometrics, and predictive analytics become powerful tools to drive game agent behaviors and further enhance student learning and performance. In conventional simulations training, deficiencies or gaps in student and player performance are often exposed only randomly when adversary behaviors are exhibited in a way that capitalizes on weaknesses by chance or when noticed and directed by human instructor intervention. Students often only learn to understand and correct their deficiencies when they directly experience failure in this way. However, according to the present disclosure, and in a much more proactive and effective way, tutor process 110 may actively monitor, predict, and identify student deficiencies and errors, and then trigger adversary intelligent agent behaviors precisely to exploit and expose weaknesses any time they are exhibited. The degree to which a student's weaknesses are challenged is also varied based on experience and skill level to maintain the individual within the zone of proximal development.

For example, a player may have a consistent performance weakness that causes the mobility of their visual scan to be consistently stagnant on a specific area of the display, or during a particular phase of play or operations that creates the conditions for the player to fail to react effectively to changes in game entity behaviors. In the tactical intercept use case, these deficiencies may manifest themselves in the form of late recognition and response to critical actions exhibited by any game entity including friendly, unknown, or hostile aircraft. During conventional intercept training, whether simulated or performed with live aircraft, these performance gaps would only be exposed when participants randomly exhibited behaviors that happened to take advantage of and expose a weakness. On the other hand, with the present disclosure, tutor process 110 may identify underlying deficiencies in player behavior through real-time or predictive data analysis, and then trigger the following example and non-limiting interventions: (1) Any combination of visual, aural, or voice cues prompts to the player making them aware of their performance deficiency. (2) Any combination of visual, aural, or voice instruction prompts and guidance information that actively assists the player in modifying their performance to correct the deficiency. (3) Changes in the behavior of game entities specifically to exploit a player performance deficiency. (4) Real-time and debrief feedback to enhance insight development, learning, and performance improvement.

In some implementations, tutor process 110 may use a variation in intelligent tutor adapting learning approaches that modifies the relationship or uses varied combinations between the separate or integrated use of rules-based algorithms and AI predictions to trigger and drive adaptive learning events. In the example case of tactical intercept training, suppose tutor process 110 identifies that an individual consistently demonstrates slow recognition of adversary behavior changes during a specific phase of the intercept. In play using the simulation, tutor process 110 may initiate triggers of adaptive learning events that target and expose identified weaknesses, including, e.g., initiating adversary maneuvers precisely at the moment the player's performance is most susceptible to the changes, as discussed above. These events enable the player to rapidly identify, develop learning insights, and correct learning and performance deficiencies in ways that are simply not possible through conventional training and simulation methods.

In some implementations, the adaptive threat behaviors may also be based on a hybrid set of rules and AI predictions that will adapt to players over time. Because they are based partially on individual attributes like, e.g., currency, experience, qualifications, performance history, etc. they may be tailored to each player. Adaptive threat behaviors will be substantially impacted by player performance deficiencies such as poor situational awareness or decision making. For example, if the game recognizes that the player has not noticed a maneuvering threat group and alerted a blue fighter, adaptive threat behaviors may be triggered to cause the adversaries to turn hot and engage unsuspecting blue fighters. As another example in an emergency management scenario, if an on-scene commander was distracted by another incident and failed to act on observed smoke and threat of fire, adaptive behaviors may be triggered to create an explosion or conflagration that would highlight the players deficiency and help to show them the consequences of such a mistake. It will be appreciated that other adaptive behaviors may be triggered without departing from the scope of the present disclosure.

In some implementations, RAI 404 may be part of tutor process 110, or may be a separate application that enables (e.g., via tutor process 110) instructional designers to create and manage RBTE computations. RAI 404 UI may enable developers to interact with each RBTE component model for easier interfacing. For instance, and referring at least to the example implementation of FIG. 5, an example diagrammatic view of components of RAI 404 is shown.

(1) Framework 500. In some implementations, tutor process 110 may monitor the simulation scenario for one of a predicted performance of the user, the input data from the user participating in the simulation scenario, and the input data from the simulation scenario. For example, the framework may establish the base structure to process understanding of the above-noted input data variables, interventions, and tags simulation system 400 and/or client electronic device 138 may use to facilitate the desired play and learning outcomes. The simulation framework is unique and may use a distinct object list (or other structure) created in the RAI, such as: (a) Independent Variables (IVs), which may be parameters in the game that are monitored by tutor process 110. IVs, such as IVs 506, may be either raw data or feature engineered by simulation system 400 to provide more insight. Examples of IVs may include those described above. (b) Intervention Structures (ISs), such as ISs 508, may be structures for ALEs, which may include an Intervention Name, as well as desired options and values for triggering and/or executing the intervention event. This provides course authors the ability to create vast number of unique ALE interventions, and more directly control how tutor process 110 interacts with the student or player in the simulation. Examples of ISs may include those described above.
(iii) Tags, such as tags 510, may be described as strings that group together IVs to allow grouping and prevent repetition when writing course software. IVs are given tags on IV creation to perform grouping. Examples of tags 510 may include those described above.

(2). Rulebook 502—A rulebook may contain the framework rules that work within, as well as list (or other structure) of rule definitions for an application. Such rules may be derived from policy, regulations, doctrine, or some other form of scenario guidance which may serve to help define bounding conditions or triggers for simulation behaviors. Rules may also be used to establish bounding conditions for AI predictions or prescriptive triggers to ensure simulated behaviors are maintained within reasonable and realistic parameters for the scenario domain. In some implementations, RAI 404 may export one or more rulebooks stored in the rulebook repository, that may be used by RBTE 410 of simulation system 400. (3) Rule 504—Rules may be generally described as a list of filtered triggers that when all the parameters are met, initiate or “fire” (trigger, execute, etc.) an intervention (ALE). A list of filtered interventions matching the appropriate simulation parameters of the input data may determine which specific intervention should be fired.

Referring at least to the example implementation of FIG. 6, example options for triggers are shown. For instance, one option is shown as an example filter trigger 600a and 600b. In some implementations, tutor process 110 may match 324 one of the predicted performance of the user, the input data from the user participating in the simulation scenario, and the input data from the simulation scenario to a rule of a plurality of rules. For instance, filter triggers may be queries used by tutor process 110 to look for specified parameters in the currently running simulation scenario, whether established by the above-noted pre-established rules or the above-noted AI predictions, and if specified parameters are met, tutor process 110 may trigger one or more interventions that match. Authors may filter using IVs, Tags, or the triggering of other rules. In some implementations, filter triggers may either require all filters to be true (as shown in 600a to match) or only some of the triggers need to be true (as shown in 600b where one of the values must be true to match). Another example option is shown as example trigger groups 602. Trigger Groups used by tutor process 110 to expand the filtering options. Each filter group may be an outside AND operator. Another example option is shown as example intervention 604. Interventions are Intervention Structures (ISs) with selected options. Multiple different interventions may be implemented using the same IS, as shown in intervention 604. Another example option is shown as example filter intervention 606. Filter interventions allow one rule to have multiple possible intervention possibilities. On the rule intervention, tutor process 110 may enable an author to add filters that need to be true to fire (i.e., trigger) the intervention. If the filters are not true, then the rule will proceed through the list (or other structure) looking for the next intervention criteria to determine if the triggering criteria is met.

It will be appreciated after reading the present disclosure that tutor process 110 (e.g., via simulation application 120 and/or simulation system 400) may be integrated into or otherwise used by any training application, including simulation systems, legacy computer-based training applications, extended reality (XR) based interactive training systems including virtual (VR), mixed, and augmented reality, etc. For example, tutor process 110 may be used to provide virtual coaching to an individual using an augmented reality solution to practice the performance of maintenance inspections or tasks on physical systems such as vehicles, support equipment, facilities, or other infrastructure. In this case, tutor process 110 may sense that the individual is experiencing difficulty performing a step in a task and provide the individual with augmented reality suggestions, cues, prompts, guidance or other forms of intervention and adaptive learning events.

In some implementations, in addition to simulated training, tutor process 110 and/or the pre-trained AI models may be integrated into an actual C2 operating system, whether a fixed or mobile ground, air, or maritime based C2 system, etc., to monitor environments, sensors, indications, behaviors, and operator actions to provide C2 operators with real-time feedback and interventions based on their observed performance and predictions of future performance. In addition to the above-described feedback for the simulations, example and non-limiting feedback that may also be provided to actual and/or simulated C2 systems may include, e.g.: a. Positive affirmation that a communication was completed correctly. b. Prompting that an action or call will be needed within a specified period of time. c. Cueing to enhance situational awareness by alerting the C2 operator that there has been a significant event or change in their operating picture. d. Prompting that some action or communication is required based on changes in the operating picture including new behaviors or sensor indications from tracked entities. e. Prompting to inform the C2 operator that predictive biometrics have detected conditions indicating potentially suboptimal human performance such as fatigue, frustration, or task saturation.

As discussed above and referring also at least to the example implementations of FIGS. 3-12, tutor process 110 may receive 702, by a computing device, input data from a user participating in a simulation scenario, wherein the input data may include biometric data. Tutor process 110 may receive 304 input data from the simulated scenario. Tutor process 110 may determine 706 that the biometric data of the user is indicative of suboptimal performance in at least one parameter of the simulation scenario. Tutor process 110 may trigger 710 an intervention event in the simulation scenario based upon, at least in part, determining that the biometric data of the user is indicative of suboptimal performance in the at least one parameter of the simulation scenario.

In some implementations, tutor process 110 may receive 702 input data from a user participating in the simulation scenario, wherein the input data may include biometric data. For instance, in some implementations, the input data (e.g., I/O request 115) from the user participating in the simulation scenario may include user biometrics (e.g., gaze tracking, gaze association with objects, entities, and dwell time, pupillometry, voice parameters, heart rate, respiration rate, brain activity, or other parameters), user performance data (e.g., experience level, performance history, currency of performance and training, UI input actions, communications calls and other performance measures, etc.).

In some implementations, tutor process 110 may receive 304 input data from the simulation scenario, wherein the input data from the user participating in the simulation scenario and the input data from the simulation scenario may be processed using feature engineering data. For instance, in some implementations, the input data (e.g., I/O request 115) from the simulation scenario may include game state data (e.g., defining scenarios, start and ending conditions, game entities, entity positions, entity behaviors, event data or other game data). In some implementations, input data from the user or the simulation scenario may be received and stored in memory or other storage device type for access and/or analysis.

In some implementations, tutor process 110 may analyze the input data from the user participating in the simulation scenario and the input data from the simulation scenario, and in some implementations, tutor process 110 may provide feedback to the user participating in the simulation scenario based upon, at least in part, analyzing the input data from the user participating in the simulation scenario and the input data from the simulation scenario. For instance, tutor process 110 may take the input from simulation system 400 such as game events, aircraft group positions, player performance, and human performance biometrics information, including, e.g., eye tracking, to provide to both feature engineering module 408 and RBTE 410 module. Feature engineering module 408 (e.g., via tutor process 110) may perform programmed engineering, as discussed above, on the provided inputs and then send the results to MLBAM 406 to make (e.g., via tutor process 110) predictions about player performance, which may then be sent to RBTE 410. LRS 412 (e.g., via tutor process 110) may send previous (historical) data, as well as receive new outputs of RBTE 410. In some implementations, players may receive feedback during play in real-time, as well as during post run debriefs. In some implementations, debrief sessions following each scenario may incorporate detailed insights generated by AI-driven analysis, including context-specific narratives created by LLMs to help users understand their performance gaps and strategies for improvement.

In some implementations, tutor process 110 may determine 706 that the biometric data of the user is indicative of suboptimal performance in at least one parameter of the simulation scenario, and in some implementations, determining that the biometric data of the user is indicative of suboptimal performance in the at least one parameter of the simulation scenario may be based upon, at least in part, matching 724 the biometric data from the user participating in the simulation scenario and the input data from the simulation scenario to a rule of a plurality of rules. For example, as will be discussed in greater detail below, RBTE 410 may (e.g., via tutor process 110) process the above-noted data inputs and monitor play to identify event parameters that call for initiation of appropriate intervention events, also referred to herein as Adaptive Learning Events (ALE). When RBTE 410 (e.g., via tutor process 110) identifies a trigger for a particular ALE, tutor process 110 may command an ALE to fire (trigger) in the simulation running on client electronic device 138.

In some implementations, tutor process 110 may predict 318 performance of the user in the simulation scenario to generate a predicted performance of the user, and in some implementations, predicting performance of the user in the simulation scenario to generate the predicted performance of the user may include processing 320, using a trained predictive model, the input data from the user participating in the simulation scenario and the input data from the simulation scenario processed using feature engineering data. For instance, MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBTE 410. In some implementations, processed data may include game state and event data, player performance data, and human performance biometrics data, etc. In some implementations, tutor process 110 may be integrated into larger-scale live, virtual, and constructive (LVC) training architectures, including massive multi-player online game environments, to support distributed mission training across multiple domains and platforms. In these scenarios, tutor process 110 and the enabled NPC entities may be selectively introduced to fill roles where no live participants are available. For example, during an emergency management scenario where a dispatcher trainee is supported by a live police responder but lacks a live fire responder, a tutor process 110 generated NPC can be inserted to fulfill that critical role. By seamlessly incorporating NPCs into the virtual networked environment, tutor process 110 may ensure comprehensive, flexible, and fully resourced training, decoupling performance and readiness objectives from scheduling and personnel availability constraints. In some implementations, roles available to be used in a simulation may be pre-determined and included in a menu for selection. When a role is selected, the NPC would then behave in a way established by doctrine and standards which would allow live players to train with and practice realistic interactions.

In some implementations, training data for the trained predictive model may include independent variables, and wherein the independent variables may include at least one of user biometrics, user performance data, game state data, historical user biometrics, historical user performance data, and historical game state data. For instance, at the heart of MLBAM 406 is a predictive model (e.g., of tutor process 110) that may be pre-trained on historical performance data (e.g., user input data and/or simulation scenario input data) to recognize player patterns and deviations from the new, real-time input data of the currently running simulation. In some implementations, the training data may include the following example and non-limiting variables:

1. Independent Variables (IV) such as: (a) Game state data defining scenarios, start and ending conditions, game entities, entity behaviors, event data or other game data. (b) Player performance data including experience level, performance history, currency of performance and training, UI input actions, communications calls and other performance measures. (c) Player human performance biometrics including gaze tracking, gaze association with entities and dwell time, pupillometry, voice parameters, and potentially heart rate, respiration rate, brain activity or other physiology parameters being monitored in response to stimulus and/or stressors of game play.

In some implementations, the above-noted training data for the trained predictive model may include dependent variables, and in some implementations, the dependent variables may include at least one of communication performance of the simulation scenario and event outcomes of the simulation scenario. For example:

2. Dependent or Predictor Variables including: (a) Measures of communication performance and effectiveness such as timeliness, accuracy, completeness, and adherence to standards or other measures. (b) Measures of event or mission outcomes.

Generally, the pre-trained model may serve as MLBAM 406 decision making entity. MLBAM 406 predictions may be relayed (e.g., via an output interface) to RBTE 410 where they may be processed by tutor process 110 with additional rules-based algorithms and evaluated as potential ALE triggers, as discussed above.

In some implementations, triggering the intervention event may include at least one of adjusting 312 a difficulty level of the simulation scenario. For example, ALEs may be used to help keep the player in the zone of proximal development and adapt to their skill level and learning needs, so they will improve at the optimum rate. When a student is being challenged at a high level, ALEs may be triggered that will provide assistance or implement subtle changes in play that reduce difficulty level, as discussed above. Conversely, ALEs may be initiated during play to make scenarios more challenging for a high performing student or player so they will be pushed to develop higher level skills more quickly. In some implementations, triggering the intervention event may include providing 314 at least one of a visual cue, an audio cue, a virtual instructor cue, and a virtual instructor intervention. For instance, a few examples of simulation application's ALEs may include, e.g.: (1) Visual cueing to prompt the student's attention to critical events, such as aircraft maneuvers or failing to initiate needed communication in a timely manner. These ALE cues may be triggered by a player's delays in communicating relevant information, or when a player's biometrics gaze tracking detects an ineffective visual scan. (2) Audio cueing to reinforce correct player communications which may be triggered when the radio communication meets all the evaluation criteria. (3) Virtual instructor cueing for incorrect communication cadence or poor radio discipline. This ALE may be triggered by a player's voice biometric detection of a slow or erratic pattern of speech or keying the radio and not speaking in a timely manner, or saying the wrong thing compared to what should have been said according to the evaluation criteria. (4) Virtual instructor intervention with pausing of the scenario when critical C2 information is missed by the player or inaccurate to the degree it would cause mission failure. An example of this ALE may be if the player incorrectly identified a friendly aircraft as hostile.

In some implementations, a player's performance may be evaluated using speech recognition, which may be performed by taking the audio of the player and interpreting it with, e.g., an appropriate Speech Recognition Grammar Specification (SRGS) file, machine learning model, such as a large language model or other deep learning model, or transformer, although other speech recognition models or any other types of relevant models may also be used. This file may specifically outline all possible audible communications a player could make and may enable tutor process 110 to categorize each word, phrase, cadence, tone, etc. as well as the overall communication type. In the C2 serious game simulation use case, the SRGS may include alignment to Air Land Sea Space Application (ALSSA) standards for multi-service tactics, techniques, and procedures for Air Control Communications with the flexibility to modify or extend specifications to adapt to changing needs or operating domains. In some implementations, tutor process 110 may make use of recorded player communication data to train a generative AI model that may be used to interpret and evaluate player communication and replace and/or supplement the use of the SRGS file.

In some implementations, tutor process 110 may trigger 710 an intervention event in the simulation scenario based upon, at least in part, determining that the biometric data of the user is indicative of suboptimal performance in at least one parameter of the simulation scenario, and in some implementations, triggering the intervention event may include triggering 316 an agent behavior in the simulation scenario. For instance, in addition to informing and triggering ALEs in real-time game play and providing intelligent tutoring feedback, the game performance data, biometrics, and predictive analytics become powerful tools to drive game agent behaviors and further enhance student learning and performance. In conventional simulations training, deficiencies or gaps in student and player performance are often exposed only randomly when adversary behaviors are exhibited in a way that capitalizes on weaknesses by chance or when noticed and directed by human instructor intervention. Students often only learn to understand and correct their deficiencies when they directly experience failure in this way. However, according to the present disclosure, and in a much more proactive and effective way, tutor process 110 may actively monitor, predict, and identify student deficiencies and errors, and then trigger adversary intelligent agent behaviors precisely to exploit and expose weaknesses any time they are exhibited. The degree to which a student's weaknesses are challenged is also varied based on experience and skill level to maintain the individual within the zone of proximal development.

For example, a player may have a consistent performance weakness that causes the mobility of their visual scan to be consistently stagnant on a specific area of the display, or during a particular phase of play or operations that creates the conditions for the player to fail to react effectively to changes in game entity behaviors. In the example, the biometric data is the gaze of the player, and the parameter is the visual scan on the area of display. In the tactical intercept use case, these deficiencies may manifest themselves in the form of late recognition and response to critical actions exhibited by any game entity including friendly, unknown, or hostile aircraft. During conventional intercept training, whether simulated or performed with live aircraft, these performance gaps would only be exposed when participants randomly exhibited behaviors that happened to take advantage of and expose a weakness. On the other hand, with the present disclosure, tutor process 110 may identify underlying deficiencies in player behavior through real-time or predictive data analysis, and then trigger the following example and non-limiting interventions: (1) Any combination of visual, aural, or voice cues prompts to the player making them aware of their performance deficiency. (2) Any combination of visual, aural, or voice instruction prompts and guidance information that actively assists the player in modifying their performance to correct the deficiency. (3) Changes in the behavior of game entities specifically to exploit a player performance deficiency. (4) Real-time and debrief feedback to enhance insight development, learning, and performance improvement.

It will be appreciated after reading the present disclosure that any other biometric data may be used as well, and in any combination, and the parameters indicative of suboptimal performance may thus correlate. For instance, in some implementations, the player's voice may be the biometric data and the parameter of the simulation scenario may be the proper cadence, tone, word use, etc. Other examples of performance parameters may include factors such as timeliness of an action or communication, accuracy of information communicated, completeness of communication, adherence to doctrine and standards, slow or ineffective visual scan, etc. In some implementations, a weighted score may be used by tutor process 110 to determine whether an intervention is warranted. For example, cadence may be weighted 0.1, gaze may be weighted 0.9, etc., and based on the total score passing a threshold score, an intervention may be triggered. In some implementations, based on the user's/player's qualification level, currency, experience, play history, trends, etc. (which may be stored in a profile of simulation system 400/real-world system 1200), the weighs may be changed. As such, the use of any particular biometric data or parameter (or any combinations thereof) should be taken as example only and not to otherwise limit the scope of the present disclosure.

In some implementations, tutor process 110 may determine 708 a time when the intervention is to be triggered during the simulation, and in some implementations, determining the time when the intervention is to be triggered during the simulation may be determined based upon, at least in part, monitoring 722 the simulation scenario for one of a predicted performance of the user, the input data from the user participating in the simulation scenario, and the input data from the simulation scenario. For example, tutor process 110 may dynamically analyze input data from both the user participating in the simulation scenario and the simulation scenario itself. Tutor process 110 may provide feedback and generate intervention events to proactively address identified user performance deficiencies. For instance, tutor process 110 may take input data from simulation system 400, such as operational events, vehicle group positions, responder current and historical performance, responder experience and qualification level, and human performance biometrics (e.g., eye tracking, heart rate, and voice tone), to drive intelligent adaptive behaviors in simulation entities.

In some implementations, tutor process 110 leverages advanced AI tools, including large language models (LLMs) and transformer-based architectures, to process user and scenario data in real-time, enabling predictive and prescriptive analytics. Predictive analytics may identify performance gaps by analyzing features such as delayed decision-making during crisis scenarios, inconsistent task prioritization, or insufficient communication. As such, tutor process 110 may use prescriptive analytics to then dynamically generate interventions, such as modifying the behaviors of simulation agents to challenge identified deficiencies, exposing users to learning opportunities tailored to their zone of proximal development. The described functionality enables tutor process 110 to adaptively modify simulation behaviors in ways that are simply not achievable through conventional training systems. For example, if tutor process 110 identifies that a user demonstrates slow recognition of critical operational changes, it may trigger adaptive behaviors in simulated responders, threats, or logistical entities at the moment when it is determined that the user's performance is most vulnerable. Taking input from the player, such as biometric data and response times, tutor process 110 may predict the players likelihood of success of certain events, and tutor process 110 may use this prediction along with other variables described throughout to alter simulation behavior to capitalize on the player's observed or predicted performance deficiency. For instance, if a player is focused on a different area of the screen for too long or has failed to respond effectively to a voice or chat communication event, or some other simulation indication during a critical scenario event, tutor process 110 may recognize this lack of awareness and exercise initiative in the simulation to exploit and expose the performance deficiency leading to a poor mission outcome. These interventions, especially when introduced at the moment the user is the most vulnerable (i.e., the moment when the user's error will result in the most negative impact or score on the simulation outcome for the user) ensure that users are continuously challenged at an optimal level, fostering rapid skill acquisition and retention. For instance, assume for example purposes only that tutor process 110 recognizes that the user is “daydreaming” and gazing off outside the prescribed area of view, which would not matter as much without any maneuvering threat group around, and thus would not be a motivating scenario to teach the user to better focus in the prescribed area of view. However, now assume in the example that when tutor process 110 recognizes that the user is gazing off outside the prescribed area of view, tutor process 110 now triggers the intervention event of the maneuvering threat group turning turn “hot” and engaging the user with a simulated weapon. The use of timing of the intervention at the point where the user's simulation outcome/score would suffer the greatest failure may help best teach the user to avoid the behavior that caused the intervention to trigger in the first place. In a conventional simulation, the system would be unaware of such performance deficiencies and the probability of a high-consequence event occurring precisely at a time that would expose a performance weakness would be a random occurrence thereby vastly increasing the potential for unrecognized performance deficiencies as well as slower progression from novice to expert.

As such, tutor process 110 may identify when a player has failed to recognize a change in game state, or is late to implement an action, or makes an incorrect action, and then take an appropriate action, tutor process 110 may trigger the threat in the simulation to take an action that will exploit this mistake. The threat action may be triggered as soon as the player exceeds the established acceptable response time, gaze time, tone, cadence, etc.

In some implementations, tutor process 110 may use a variation in intelligent tutor adapting learning approaches that modifies the relationship or uses varied combinations between the separate or integrated use of rules-based algorithms and AI predictions to trigger and drive adaptive learning events. In the example case of tactical intercept training, suppose tutor process 110 identifies that an individual consistently demonstrates slow recognition of adversary behavior changes during a specific phase of the intercept. In play using the simulation, tutor process 110 may initiate triggers of adaptive learning events that proactively target and expose identified weaknesses, including, e.g., initiating adversary maneuvers precisely at the moment the player's performance is most susceptible to the changes, as discussed above. These events enable the player to rapidly identify, develop learning insights, and correct learning and performance deficiencies as they are identified by tutor process 110.

In some implementations, the adaptive threat behaviors may also be based on a hybrid set of rules and AI predictions that will adapt to players over time. Because they are based partially on individual attributes like, e.g., currency, experience, qualifications, performance history, etc. they may be tailored to each player. Adaptive threat behaviors will be substantially impacted by player performance deficiencies such as poor situational awareness or decision making. For example, if the game recognizes that the player has not noticed a maneuvering threat group and alerted a friendly fighter, adaptive threat behaviors may be triggered to cause the adversaries to turn toward and engage unsuspecting friendly fighters. As another example in an emergency management scenario, if an on-scene commander was distracted by another incident and failed to act on observed smoke and threat of fire, adaptive behaviors may be triggered to create an explosion or conflagration that would highlight the players deficiency and help to show them the consequences of such a mistake. It will be appreciated that other adaptive behaviors may be triggered without departing from the scope of the present disclosure.

In some implementations, RAI 404 may be part of tutor process 110, or may be a separate application that enables (e.g., via tutor process 110) instructional designers to create and manage RBTE computations. RAI 404 UI may enable developers to interact with each RBTE component model for easier interfacing. For instance, and referring at least to the example implementation of FIG. 5, an example diagrammatic view of components of RAI 404 is shown.

(1) Framework 500. In some implementations, tutor process 110 may monitor the simulation scenario for one of a predicted performance of the user, the input data from the user participating in the simulation scenario, and the input data from the simulation scenario. For example, the framework may establish the base structure to process understanding of the above-noted input data variables, interventions, and tags simulation system 400 and/or client electronic device 138 may use to facilitate the desired play and learning outcomes. The simulation framework is unique and may use a distinct object list (or other structure) created in the RAI, such as: (a) Independent Variables (IVs), which may be parameters in the game that are monitored by tutor process 110. IVs, such as IVs 506, may be either raw data or feature engineered by simulation system 400 to provide more insight. Examples of IVs may include those described above. (b) Intervention Structures (ISs), such as ISs 508, may be structures for ALEs, which may include an Intervention Name, as well as desired options and values for triggering and/or executing the intervention event. This provides course authors the ability to create vast number of unique ALE interventions, and more directly control how tutor process 110 interacts with the student or player in the simulation. Examples of ISs may include those described above.
(iii) Tags, such as tags 510, may be described as strings that group together IVs to allow grouping and prevent repetition when writing course software. IVs are given tags on IV creation to perform grouping. Examples of tags 510 may include those described above. (2). Rulebook 502—A rulebook may contain the framework rules that work within, as well as list (or other structure) of rule definitions for an application. Such rules, as would be understood by those skilled in the art after reading the present disclosure, may be derived from policy, regulations, doctrine, or some other form of scenario guidance which may serve to help define bounding conditions or triggers for simulation behaviors. Rules may also be used to establish bounding conditions for AI predictions or prescriptive triggers to ensure simulated behaviors are maintained within reasonable and realistic parameters for the scenario domain. In some implementations, RAI 404 may export one or more rulebooks stored in the rulebook repository, that may be used by RBTE 410 of simulation system 400.

(3) Rule 504—Rules may be generally described as a list of filtered triggers that when all the parameters are met, initiate or “fire” (trigger, execute, etc.) an intervention (ALE). A list of filtered interventions matching the appropriate simulation parameters of the input data may determine which specific intervention should be fired.

Referring at least to the example implementation of FIG. 6, example options for triggers are shown. For instance, one option is shown as an example filter trigger 600a and 600b. In some implementations, tutor process 110 may match 324 one of the predicted performance of the user, the input data from the user participating in the simulation scenario, and the input data from the simulation scenario to a rule of a plurality of rules. For instance, filter triggers may be queries used by tutor process 110 to look for specified parameters in the currently running simulation scenario, whether established by the above-noted pre-established rules or the above-noted AI predictions, and if specified parameters are met, tutor process 110 may trigger one or more interventions that match. Authors may filter using IVs, Tags, or the triggering of other rules. In some implementations, filter triggers may either require all filters to be true (as shown in 600a to match) or only some of the triggers need to be true (as shown in 600b where one of the values must be true to match). Another example option is shown as example trigger groups 602. Trigger Groups used by tutor process 110 to expand the filtering options. Each filter group may be an outside AND operator. Another example option is shown as example intervention 604. Interventions are Intervention Structures (ISs) with selected options. Multiple different interventions may be implemented using the same IS, as shown in intervention 604. Another example option is shown as example filter intervention 606. Filter interventions allow one rule to have multiple possible intervention possibilities. On the rule intervention, tutor process 110 may enable an author to add filters that need to be true to fire (i.e., trigger) the intervention. If the filters are not true, then the rule will proceed through the list (or other structure) looking for the next intervention criteria to determine if the triggering criteria is met.

It will be appreciated after reading the present disclosure that tutor process 110 (e.g., via simulation application 120 and/or simulation system 400) may be integrated into or otherwise used by any training application, including simulation systems, legacy computer-based training applications, extended reality (XR) based interactive training systems including virtual (VR), mixed, and augmented reality, etc. For example, tutor process 110 may be used to provide virtual coaching to an individual using an augmented reality solution to practice the performance of maintenance inspections or tasks on physical systems such as vehicles, support equipment, facilities, or other infrastructure. In this case, tutor process 110 may sense that the individual is experiencing difficulty performing a step in a task and provide the individual with augmented reality suggestions, cues, prompts, guidance or other forms of intervention and adaptive learning events.

In some implementations, in addition to simulated training, tutor process 110 and/or the pre-trained AI models may be integrated into an actual C2 operating system, whether a fixed or mobile ground, air, or maritime based C2 system, etc., to monitor environments, sensors, indications, behaviors, and operator actions to provide C2 operators with real-time feedback and interventions based on their observed performance and predictions of future performance. In addition to the above-described feedback for the simulations, example and non-limiting feedback that may also be provided to actual and/or simulated C2 systems may include, e.g.: a. Positive affirmation that a communication was completed correctly. b. Prompting that an action or call will be needed within a specified period of time. c. Cueing to enhance situational awareness by alerting the C2 operator that there has been a significant event or change in their operating picture. d. Prompting that some action or communication is required based on changes in the operating picture including new behaviors or sensor indications from tracked entities. e. Prompting to inform the C2 operator that predictive biometrics have detected conditions indicating potentially suboptimal human performance such as fatigue, frustration, or task saturation.

As discussed above and referring also at least to the example implementations of FIGS. 3-12, tutor process 110 may receive 802 input data from a user participating in a live operation (e.g., real-time tactical command and control (C2)), whether for the purpose of performing training or accomplishing a mission. Tutor process 110 may receive 804 input data from the C2 operational system or connected sensors/data sources. Tutor process 110 may analyze 806 the input data from the user participating in the live operation and the input data from the C2 operational system. Tutor process 110 may provide 808 feedback to the user participating in the live operation based upon, at least in part, analyzing the input data from the user participating in the live operation and the input data from the live operation (e.g., via a C2 operational system of tutor process 110, such as real-world system 1200).

As used herein, the terms ‘environment,’ ‘scenario,’ ‘operation,’ ‘simulation,’ ‘training scenario,’ or ‘game’ refer broadly to any context in which the present disclosure may be implemented. Unless otherwise specified, these terms are not intended to limit the scope of the present disclosure. For instance, a ‘game’ may represent a fully simulated training exercise, while a ‘scenario’ may refer to either a simulated event, a live operational setting, or a hybrid live, virtual, and constructive (LVC) environment that integrates both real and simulated elements. When describing the Virtual Assistant (VA) and its functionalities, references to ‘live operations’ indicate the VA is supporting real-world, ongoing missions, whereas references to ‘training scenarios’ or ‘simulations’ indicate a non-real or partially constructed operational environment intended for skill development and assessment. The VA may also operate in LVC settings, seamlessly adapting its prescriptive feedback to both real and simulated data sources to enhance performance and achieve desired outcomes.

As used herein, the term “tutor process” may be used interchangeably with “virtual assistant process”. As such, the specific use of the word “tutor” should not be taken to limit the present disclosure to training/teaching/simulation applications, as real-world applications are also contemplated. For instance, the following description is similar to the description above, except instead of a serious game training and/or real-world simulation system for C2 applications, tutor process 110 may be used as a virtual assistant during live (i.e., real-world) applications; however, it will be appreciated after reading the present disclosure that any type of applications and any types of live purposes may be used with the present disclosure. As such, the description of any particular real-world system for C2 applications should be taken as example only and not to otherwise limit the scope of the present disclosure. It will also be appreciated after reading the present disclosure that while an advantage of the present disclosure is the ability to be executed on a local client electronic device, the functionality of tutor process 110 may also be executed using the above-noted legacy systems without departing from the scope of the present disclosure.

In some implementations, tutor process 110 enables a virtual assistant system accessed through an application installed on, e.g., an operational C2 system, whether installed in a fixed or mobile command center, naval vessel, C2 aircraft, or other mobile system (e.g., such as client electronic device 138, 144, 142, etc. from FIG. 1 and/or FIGS. 2-3) using, e.g., a USB or installed on other connected wearable (e.g., headset, XR eyewear, etc.), connected foot-pedal device, a connected handheld pointing device (mouse), eye tracking sensor, or any other client electronic device or peripheral device. Tutor process 110 may be fully self-contained and integrated within the C2 operating system software (e.g., of tutor process 110) and may access C2 network and datalink data, as well as the internet through an ethernet connection or other wired/wireless methods/network(s), such as those discussed throughout, which may also be used to download applications to run locally and/or run applications remotely. Data services, as used herein, may generally refer to the storage, retrieval, and management of game-related data, whether hosted on local servers, cloud-based infrastructure, or a hybrid combination thereof. Voice services may generally refer to AI-enabled natural language processing capabilities (e.g., ASR, NLU, NLP, etc.) for, e.g., converting speech to text and text to speech, implemented on client devices, on-site systems, cloud resources, or through hybrid configurations. Data and/or voice services may be installed locally on client electronic device 138 without the need for connection to any form of commercial internet, and/or through commercial/government networks. In some implementations, applications and/or tutor process 110 may be supported via a web-based data architecture, on premises network and data storage, or hybrid cloud that uses a combination of local on-premises, cloud, and client data architecture components.

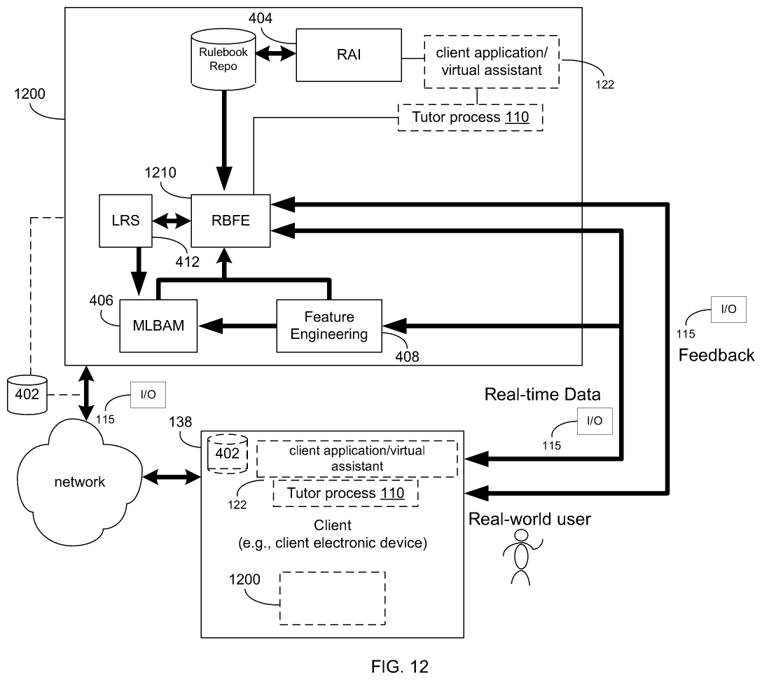

In some implementations, as will be discussed further below, data may be captured by tutor process 110 within a real-time data gathering application and may communicate with a datastore (or other type of storage architecture) to access such things as, e.g., user authentication information, user assessment data, user feedback, previous user training events view information, user logins, application updates, organization information, application logs, and various other tutor process 110 information. In some implementations, tutor process 110 may integrate multiple processes to deliver a comprehensive, adaptive, and proactive virtual assistant environment. For example, the Machine Learning Biometric Assessment Module (MLBAM) portion of tutor process 110 may apply predictive analytics to user biometrics (e.g., gaze, voice cadence, pupillometry) and conventional performance measures, identifying hidden performance factors like cognitive load before errors occur. The Rules-Based Tutoring Engine (RBTE) portion of tutor process 110 may then leverage these predictive insights to match conditions against authored rule sets, ensuring that any identified errors are brought to the user's attention in real-time to be remedied. In some implementations, tutor process 110 may employ prescriptive analytics to not only anticipate user needs but also prescribe live operation adjustments and cueing strategies that shape improved human performance. This unified approach transcends simple scripted scenarios or static decision trees, enabling continuous, embedded live improvements across a range of domains, and is further poised for enhancements in personalization, sensor integration, interoperability, and scalable authoring-ultimately supporting diverse applications from live military C2 environments to live medical scenarios, and live industrial control systems. For instance, and referring at least to the example implementation of FIG. 12, an example real-world system (e.g., real-world system 1200) is shown. In the example, similarly as discussed above, the above-noted datastore (e.g., datastore 402) may be operatively connected to the client (e.g., such as client electronic device 138, 144, 142, etc. from FIG. 1 and/or FIGS. 2-3). For ease of explanation, assume that the client is client electronic device 138. These capabilities may also be deployed on a wide range of architectures, including but not limited to on-premises servers, mobile or transportable servers, web-based real-world instances, and hybrid configurations, thus providing flexible deployment options that can be tailored to diverse operational constraints or network topologies.

Similarly to FIG. 4 discussed above, real-world system 1200 may also include a Rule Authoring Interface (RAI), such as RAI 404, a Machine Learning Biometric Assessment Module (MLBAM), such as MLBAM 406, a feature engineering engine module, such as feature engineering module 408, a Rules Based Feedback Engine (RBFE) Module, such as RBFE 1210, and Learning Record Store (LRS), such as LRS 412. It will be appreciated after reading the present disclosure that the components of real-world system 400 may vary in their configuration and placement, and that more or less components may be used and/or combined and/or replaced without departing from the scope of the present disclosure. It will also be appreciated after reading the present disclosure that tutor process 110 and/or client application/virtual assistant (e.g., client application 122) (as well as any portion of their functionality) may be part of real-world system 1200 or any of the components of real-world system 1200 (and vice versa), and that real-world system 1200 (e.g., via tutor process 110 and/or client application) may be a part of client electronic device 138 and may be connected wirelessly or wired to client electronic device 138 via the network. It will also be appreciated after reading the present disclosure that various alternative architectures of real-world system 1200 and/or client electronic device 138 may also be used to monitor real-world data, user performance data, and human performance biometrics to assess the need for, and trigger feedback from a virtual assistant (e.g., via client application/virtual assistant application, such as client application 122), or other interventions, including variations that do not use eye tracking or one or more other biometrics as a trigger/intervention parameter. As such, the example configurations shown in the figures and described throughout should be taken as example only and not to otherwise limit the scope of the present disclosure.

In some implementations, the domain information used by tutor process 110 may be accessed through a range of UI pages in client application 122 (e.g., via tutor process 110). Information about such things as previous training or operational events, organization information, user information, and training options, etc., may be accessed by client application 122 (e.g., via tutor process 110) through, e.g., a main menu UI (e.g., via RAI 404) that provides access to detailed information about each individual category. The main menu (e.g., via tutor process 110 and/or client application 122) may enable users to do such things as, e.g., select from a list of saved user preferences, pre-configured mission options, or review mission playback and debrief.

Generally, real-world scenarios may include numerous entities with numerous key attributes to define performance and behaviors during real-time actions which may be used by the VA to inform predictions about future behavior of real-world entities or tracks in the C2 system. This information may be stored, e.g., in datastore 402. While the following example includes aircraft entities, it will be appreciated after reading the present disclosure that other types of entities may be used without departing from the scope of the present disclosure. For example:

1. Individual and groups of entities associated with key metadata varying by role in the real-world scenario. For instance, aircraft entities may include metadata such as type/model/series, performance parameters, starting conditions, position, altitude, speed, heading, cargo or passenger capacity, flight plan, and communication logs. Other types of entities may include: (a) Ground vehicles, which may include type (e.g., emergency response, cargo, passenger transport), current position, speed, heading, cargo or passenger status, fuel level, and route information. (b) Naval vessels, which may include type/model, displacement, speed, heading, cargo, passenger or crew count, status of onboard systems (e.g., radar, communication), and docking schedules. (c) Personnel, which may include roles (e.g., responders, coordinators, operators), current position, assigned tasks, skill certifications, health status, and communication or coordination logs. (d) Unmanned systems, which may include type (e.g., drones, unmanned ground vehicles, submersibles), battery level, payload type (e.g., surveillance, delivery), operational range, and communication protocols. (e) Infrastructure, which may include fixed installations (e.g., command centers, communication towers, warehouses, docks, and piers) with associated operational status, capacity, and access restrictions. (f) Sensors, which may include devices such as weather stations, cameras, harbor radars, or traffic sensors, with metadata like detection range, accuracy, operational status, and data output type. (g) Environmental factors, which may include dynamic entities such as weather systems (e.g., storms, wind speed), tidal movements, sea state, traffic congestion, or hazardous areas. (h) Cargo and freight, which may include shipments, containers, or goods with metadata such as weight, dimensions, contents, destination, tracking information, and security status. (i) Passengers, which may include metadata such as group size, demographics, boarding status, and destination. (j) Cyber entities, which may include assets like networks, communication nodes, or data streams with metadata such as encryption level, bandwidth, latency, and security alerts. It will be appreciated after reading the present disclosure that other entities may also be associated with key metadata without departing from the scope of the current disclosure. 2. Operational overlay information, which may be defined by files in datastore 402 consisting of waypoints, fixed reference points, airspace/operational boundaries, or flight routes, entity performance attributes including, e.g., operating speeds and altitudes, payloads, sensors, communications or other capabilities, etc. or established at run time by manually entering data from mission planning information or documents. 3. Boolean parameter flags, which save live operation events and provide live user performance information on events during the live operation. 4. Operations may include, e.g., trigger events, which initiate actions performed by a virtual assistant, as will be discussed in greater detail below. Trigger logic may be derived from rule-based algorithms, predictive analytics, or a hybrid of the two. It will be appreciated after reading the present disclosure that more or less or other key attributes to define performance and behaviors during the live operation may also be used without departing from the scope of the present disclosure.

As will be discussed in greater detail below, in some implementations, live operations may play out by, e.g., aircraft groups executing a certain flight profile, events being triggered by live operational participant actions, and player input by a peripheral device, such as a keyboard, pointing device, microphone, etc., and making expected communications that may be interpreted (e.g., via speech recognition application of tutor process 110) and scored (e.g., comparing what was said or otherwise communicated by the user via voice commands, text, datalink messages, or some other form of communication with what should have been communicated according to proper protocols and standards).

In some implementations, tutor process 110 may receive 802 input data from a user participating in the live operation. For instance, in some implementations, the input data (e.g., I/O request 115) from the user participating in the live operation may include user biometrics (e.g., gaze tracking, gaze association with objects, entities, and dwell time, pupillometry, voice parameters, heart rate, respiration rate, brain activity, or other parameters), user performance data (e.g., experience level, performance history, currency of performance and training, UI input actions, communications calls and other performance measures, etc.).

In some implementations, tutor process 110 may receive 804 input data from the live C2 operational system. For instance, in some implementations, the input data (e.g., I/O request 115) from the live operational system may include live state data (e.g., the current operational environment, entities, entity behaviors, event data or other live data). In some implementations, input data from the user or the live operational system may be received and stored in memory or other storage device type for access and/or analysis.

In some implementations, tutor process 110 may analyze 806 the input data from the user participating in the live operation and the input data from the live operational system, and in some implementations, tutor process 110 may provide 808 feedback to the user participating in the live operation based upon, at least in part, analyzing the input data from the user participating in the live operation and the input data from the live operational system. This analysis may extend beyond voice inputs, sensor streams, and biometric signals to include chat communications, data link messages, text-based exchanges, and other non-verbal communication pathways between the user (or operators) in real-world operations. By interpreting and assessing these additional data sources, the system may trigger appropriate live operational feedback, ensuring comprehensive monitoring and guidance across multiple communication modalities. For instance, tutor process 110 may take the input from live system 1200 such as live events, aircraft group positions, user performance (e.g., current and/or historical performance from past live operations and/or simulations), and human performance biometrics information, including, e.g., eye tracking, to provide to both feature engineering module 408 and RBFE 1210 module. Feature engineering module 408 (e.g., via tutor process 110) may perform programmed engineering, which involves computationally processing and transforming raw data inputs (e.g., eye tracking metrics such as gaze duration or pupil dilation) into structured features that are optimized for use in predictive models. These engineered features may then be sent to MLBAM 406 to make (e.g., via tutor process 110) predictions about player performance. For example, eye tracking metrics may be used to infer cognitive load, situational awareness, or reaction times, which are incorporated into predictive algorithms to assess and forecast a user's ability to maintain task performance under varying conditions. These predictions may then be sent to RBFE 1210, which may match the results to predefined rules or generate adaptive and prescriptive feedback. LRS 412 (e.g., via tutor process 110) may send previous (historical) data, as well as new outputs of RBFE 1210. In some implementations, users may receive feedback in real-time, as well as during post event debriefs.

In some implementations, tutor process 110 may predict 818 performance of the user in the live operation to generate a predicted performance of the user, and in some implementations, predicting performance of the user in the live operation to generate the predicted performance of the user may include processing 820, using a trained predictive model, the input data from the user participating in the live operation and the input data from the live operational system processed using feature engineering data. For instance, MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBFE 1210.

In some implementations, providing feedback to the user participating in the live operation may include triggering 810 an intervention event in the live operational system based upon, at least in part the input data from the user participating in the live operation and the input data from the live operational system. For example, as will be discussed in greater detail below, RBFE 1210 may (e.g., via tutor process 110) process the above-noted data inputs and monitor real-time data to identify event parameters that call for initiation of appropriate feedback from the virtual assistant. When RBFE 1210 (e.g., via tutor process 110) identifies a trigger for a particular recommendation/feedback, tutor process 110 may command an adapted feedback engine (AFE) to fire (trigger) feedback on client electronic device 138. MLBAM 406 (e.g., via tutor process 110) may ingest the input data that has been processed (e.g., analyzed) through a feature engineering model (e.g., via feature engineering module 408) of tutor process 110, may process the data through a trained predictive model (e.g., via feature engineering module 408) of tutor process 110, and may deliver predictions to RBFE 1210. In some implementations, processed data may include live state and event data, user performance data, and human performance biometrics data, etc. At the heart of MLBAM 406 is a predictive model (e.g., of tutor process 110) that may be pre-trained on historical performance data (e.g., user input data from past, live, and/or past simulation scenarios) to recognize user patterns and deviations from the new, real-time input data of the currently live operation. In some implementations, the data may include the following example and non-limiting variables:

1. Independent Variables (IV) such as: (a) Live state data defining the operational environment, entities, entity behaviors, event data or other live data. (b) User performance data including experience level, performance history, currency of performance and training, UI input actions, communications calls and other performance measures. (c) User human performance biometrics including gaze tracking, gaze association with entities and dwell time, pupillometry, voice parameters, and potentially heart rate, respiration rate, brain activity or other physiology parameters being monitored in response to stimulus and/or stressors of the live operation.

2. Dependent or Predictor Variables including: (a) Measures of communication performance and effectiveness such as timeliness, accuracy, completeness, and adherence to standards or other measures. (b) Measures of event or mission outcomes.

Generally, the pre-trained model may serve as MLBAM 406 decision making entity. MLBAM 406 predictions may be relayed (e.g., via an output interface) to RBFE 1210 where they may be processed by tutor process 110 with additional rules-based algorithms and evaluated as potential AFE triggers. One such example is the use of voice cadence to determine whether the user is speaking too fast or too slow. The live operational system records spoken words-per-minute (WPM) as an Independent Variable and compares that value to a rule that provides a lower and upper WPM limit. If the WPM IV is above or below the rule's value, then an AFE is triggered that tells the user to “watch their comm cadence” or other such feedback.

In some implementations, triggering the intervention event may include providing 814 at least one of a visual cue, an audio cue, a virtual cue, and a virtual intervention. A few examples of AFEs may include, e.g., (1) Visual cueing to prompt the user's attention to critical events, such as aircraft maneuvers or failing to initiate needed communication in a timely manner. These AFE cues may be triggered by a user's delays in communicating relevant information, or when a user's biometrics gaze tracking detects an ineffective visual scan (e.g., not noticing something important like a hidden entity, or not looking in a particular direction for more than a predetermined amount of time, etc.). (2) Audio cueing to reinforce correct user communications which may be triggered when the radio communication meets all the evaluation criteria, or conversely, audio cueing to help remedy user communications which may be triggered when the radio communication fails to meet a threshold amount of the evaluation criteria. (3) Virtual instructor cueing for incorrect communication cadence or poor radio discipline. This AFE may be triggered by a user's voice biometric detection of a slow or erratic pattern of speech or keying the radio and not speaking in a timely manner, or saying the wrong thing compared to what should have been said according to the evaluation criteria. (4) Virtual intervention with displaying obvious visual objects on the operator's display, in a heads up display (HUD), or augmented reality device when critical C2 information is missed by the user or inaccurate to the degree it would cause mission failure. An example of this AFE may be if the user incorrectly identified a friendly aircraft as hostile, where a flashing banner might appear letting the user know they predicted to be targeting a friendly aircraft.

In some implementations, a user's performance may be evaluated using speech recognition, which may be performed by taking the audio of the user and interpreting it with, e.g., an appropriate Speech Recognition Grammar Specification (SRGS) file, although other speech recognition grammars and models may also be used. This file may specifically outline all possible audible communications a player could make and may enable tutor process 110 to categorize each word, phrase, cadence, tone, etc. as well as the overall communication type. In the C2 live operation use case, the SRGS may include alignment to Air Land Sea Space Application (ALSSA) standards for multi-service tactics, techniques, and procedures for Air Control Communications with the flexibility to modify or extend specifications to adapt to changing needs or operating domains. In some implementations, tutor process 110 may make use of recorded user communication data to train a generative AI model that may be used to interpret and evaluate user communication and replace and/or supplement the use of the SRGS file.

In some implementations, triggering the intervention event may include triggering feedback proactively during the live operation. For instance, in addition to informing and triggering adaptive feedback events in real-time live operations and providing intelligent feedback, the live performance data, biometrics, and predictive analytics become powerful tools to drive proactive feedback and further enhance performance. In conventional post scenario debriefs, deficiencies or gaps in user performance are often exposed only randomly when adversary behaviors are exhibited in a way that capitalizes on weaknesses by chance or when noticed and directed by human feedback intervention. Users often only learn to understand and correct their deficiencies when they directly experience failure in this way, which can be catastrophic during a real-world scenario. However, according to the present disclosure, and in a much more proactive and effective way, tutor process 110 may actively monitor, predict, and identify user deficiencies and errors, and then trigger proactive feedback before there is an ability for an entity to exploit and expose weaknesses any time they are exhibited.

For example, a user may have a consistent performance weakness (whether from past real-time operations or past simulations) that causes the mobility of their visual scan to be consistently stagnant on a specific area of the display, or during a particular phase of operations that creates the conditions for the user to fail to react effectively to changes in entity behaviors. In the tactical intercept use case, these deficiencies may manifest themselves in the form of late recognition and response to critical actions exhibited by any entity including friendly, unknown, or hostile aircraft. During conventional intercept live operations with live aircraft, these performance gaps would only be exposed when participants randomly exhibited behaviors that happened to take advantage of and expose a weakness, which could be fatal. On the other hand, with the present disclosure, tutor process 110 may identify underlying deficiencies in user behavior through real-time or predictive data analysis, and then trigger the following example and non-limiting interventions:

(1) Any combination of visual, aural, haptic, or voice cues prompts to the user making them aware of their performance deficiency. (2) Any combination of visual, aural, haptic, or voice instruction prompts and guidance information that actively assists the user in modifying their performance to correct the deficiency. (3) Notifications queuing the user about performance deficiencies that may make them vulnerable to certain predicted entity behaviors. (4) Real-time and debrief feedback to enhance insight development, learning, and performance improvement.

In some implementations, tutor process 110 may use a variation in intelligent tutor adaptive feedback approaches that modifies the relationship or uses varied combinations between the separate or integrated use of rules-based algorithms and AI predictions to trigger and drive adaptive feedback events. In the example case of tactical intercept live operation, suppose tutor process 110 identifies that an individual has in the past (or is currently) consistently demonstrating slow recognition of adversary behavior changes during a specific phase of the intercept. In the real-world live operation, tutor process 110 may initiate triggers of adaptive feedback events that target and expose identified weaknesses, including, e.g., warning the user that an entity might be able to initiate adversary maneuvers as a result of the slow recognition prior to the user being the most susceptible to such a negative maneuver. These events enable tutor process 110 (and thus user) to rapidly identify, develop live insights, and correct performance deficiencies in real-time.

In some implementations, the adaptive threat behaviors may also be based on a hybrid set of rules and AI predictions that will adapt to users over time. Because they are based partially on individual attributes like, e.g., currency, experience, qualifications, performance history, etc. they may be tailored to each user. Adaptive threat behaviors will be substantially impacted by user performance deficiencies such as poor situational awareness or decision making. For example, if tutor process 110 recognizes that the user has not noticed a maneuvering threat group and alerted a blue fighter, adaptive feedback may be triggered to notify the user of the error, which may also include a possible result of the error if not corrected (e.g., adversaries may turn hot and engage unsuspecting blue fighters). As another example in an emergency management live operation, if an on-scene commander was distracted by another incident and failed to act on observed smoke and threat of fire, adaptive feedback may be triggered to notify the user of the error, which may also include a possible result of the error if not corrected (e.g., an explosion or conflagration may be created). It will be appreciated that other adaptive feedback may be triggered without departing from the scope of the present disclosure.

In some implementations, RAI 404 may be part of tutor process 110, or may be a separate application that enables (e.g., via tutor process 110) live operators to create and manage RBFE 1210 computations. RAI 404 UI may enable developers to interact with each RBFE component model for easier interfacing. For instance, and referring at least to the example implementation of FIG. 5, an example diagrammatic view of components of RAI 404 is shown.

(1) Framework 500. The framework may establish the base structure to process understanding of the above-noted input data variables, interventions, and tags real-world system 1200 and/or client electronic device 138 may use to facilitate the desired corrective outcomes. The simulation framework is unique and may use a distinct object list (or other structure) created in the RAI, such as:
(a) Independent Variables (IVs), which may be parameters in the real-world live operation that are monitored by tutor process 110. IVs, such as IVs 506, may be either raw data or feature engineered by real-world system 1200 to provide more insight. Examples of IVs may include, e.g.:
   (i) Last mission conducted
   (ii) Previous mission performance tendencies
   (iii) User qualification level
   (iv) Eye gaze distance to blue air/friendly aircraft entities
   (v) Voice communication pace of speech
(b) Intervention Structures (ISs), such as ISs 508, may be structures for AFEs, which may include an Intervention Name, as well as desired options and values for triggering and/or executing the intervention event. This provides live operation authors the ability to create vast numbers of unique AFE interventions, and more directly control how tutor process 110 interacts with the user in the real-world live operation. Examples of ISs may include, e.g.:
   (i) Intervention—Warn user of upcoming communications call
   (ii) Options:
      1. Highlight entity of interest (Example: Blue Air)
         i. Values:
         1. True
         2. False
      2. Highlight area of interest (Example: Designated “Bullseye” point)
         i. Values:
         1. True
         2. False
      3. Immediate Warning
         i. Values:
         1. True
         2. False
      4. Set Text Warning Color
         i. Values:
         1. Red
         2. Green
         3. Yellow
   (iii) Tags, such as tags 510, may be described as strings that group together IVs to allow grouping and prevent repetition when writing course software. IVs are given tags on IV creation to perform grouping. Examples of tags 510 may include, e.g.:
      a. Eye Distance-IVs tagged-Gaze Distance to bullseye, Gaze Distance to Blue Air, Gaze Distance to Red Air
      b. Pupillometry—IVs tagged—Current Pupil size, Average Pupil size over scenario, Average Pupil size past 5 seconds (or other interval)

(2). Rulebook 502—A rulebook may contain the framework rules that work within, as well as list (or other structure) of rule definitions for an application. Such rules may be derived from policy, regulations, doctrine, or some other form of scenario guidance which may serve to help define bounding conditions or triggers for simulation behaviors. Rules may also be used to establish bounding conditions for AI predictions or prescriptive triggers to ensure simulated behaviors are maintained within reasonable and realistic parameters for the scenario domain. In some implementations, RAI 404 may export one or more rulebooks stored in the rulebook repository, that may be used by RBFE 1210 of real-world system 1200. (3) Rule 504—Rules may be generally described as a list of filtered triggers that when all the parameters are met, initiate or “fire” (trigger, execute, etc.) an intervention (AFE). A list of filtered interventions matching the appropriate live parameters of the input data may determine which specific intervention should be fired.

Similar to the above discussion of FIG. 6, example options for triggers may also be used for the real-world live operational system. Filter triggers may be queries used by tutor process 110 to look for specified parameters in the current live operational system, whether established by the above-noted pre-established rules or the above-noted AI predictions, and if specified parameters are met, tutor process 110 may trigger one or more interventions. Authors may filter using IVs, Tags, or the triggering of other rules. In some implementations, filter triggers may either require all filters to be true or only some of the triggers need to be true to match—similar to fuzzy logic).

Trigger Groups used by tutor process 110 may be used to expand the filtering options. Each filter group may be an outside AND operator.

Interventions are Intervention Structures (ISs) with selected options. Multiple different interventions may be implemented using the same IS.

Filter interventions allow one rule to have multiple possible intervention possibilities. On the rule intervention, tutor process 110 may enable an author to add filters that need to be true to fire (i.e., trigger) the intervention. If the filters are not true, then the rule will proceed through the list (or other structure) looking for the next intervention criteria to determine if the triggering criteria is met.

It will be appreciated after reading the present disclosure that alternative computing form factors may be used for client-based applications including, e.g., laptops, tablets, smart phones, mini-computers, desktop computers or other client electronic devices with sufficient processing capability.

Thus, when tutor process 110 is inserted into a live Command and Control (C2) operating system to serve as a virtual assistant (VA), the prescriptive analytics enable the VA (e.g., via tutor process 110) to not only predict operator performance but also prescribe interventions that elicit improved human performance crucial for meeting objectives. By continuously (or near-continuously) monitoring biometric and performance data, the VA can proactively trigger live operational adjustment recommendations, introduce resource reallocations, or provide targeted guidance-effectively maintaining real-time alignment with operational goals. This capability extends conceptually to other mission-critical or complex environments, ensuring that the system's adaptive and proactive instructional design can support optimal outcomes across a broad range of operational domains. The VA monitors real-time data streams from operational environments and operator interactions, analyzing input data from both the operational environment and the C2 operator. By providing feedback and generating intervention events, the VA enhances situational awareness, optimizes operator performance, and ensures mission-critical actions are executed effectively, even under the most demanding conditions.

In this embodiment as a virtual assistant for live operations, the system employs predictive analytics to anticipate potential performance gaps and situational awareness deficiencies before they lead to operational errors. It further applies prescriptive analytics to guide the operator toward improved outcomes by recommending or initiating timely interventions. By continuously monitoring real-time operational data, operator biometrics (e.g., gaze, voice cadence, physiological indicators), and mission context (e.g., sensor outputs, tracked entities, environmental conditions), the VA proactively provides cues, adjustments, and decision-support prompts. Rather than reacting after issues arise, this approach leverages AI-driven predictions and prescriptions to maintain optimal operator performance and alignment with mission objectives, even under complex and dynamic conditions.

The VA is designed to support operators managing multi-domain environments, where situational awareness and decision-making may span diverse domains such as air, surface, space, electronic warfare, and network operations. In addition, the VA adapts seamlessly to non-military applications, such as emergency management and logistics operations, by monitoring operational data (e.g., sensor outputs, tracked entity behaviors, and communication flows) and providing tailored feedback and interventions specific to the domain and scenario.

Advanced AI tools, e.g., large language models (LLMs), transformer-based architectures, and predictive and prescriptive analytics, enable the VA to analyze diverse inputs. These may include operator biometrics (e.g., gaze tracking, response times, and voice cadence), real-time operational data, and historical performance records. For example, the VA may detect patterns of delayed responses, task prioritization errors, or cognitive overload, using this analysis to generate prescriptive interventions that guide the operator toward high-performance behaviors.

The VA dynamically triggers a wide range of feedback and intervention prompts tailored to optimize operator performance. These may include visual alerts, auditory tones, synthetic voice instructions, haptic feedback, or other means to provide feedback. For instance, the VA may issue cues to direct operator attention toward significant changes in the operating picture or provide recommendations for immediate actions to address anomalies or evolving mission demands. The focus is on ensuring that the operator can effectively manage task saturation and complexity in real-time, maintaining peak performance in high-stakes, multi-domain environments.

Unlike conventional systems, the VA employs prescriptive analytics to deliver feedback designed not only to inform but also to elicit specific high-performance behaviors. By analyzing the demands of the operational context and the operator's current state, the VA proactively identifies potential performance risks (e.g., fatigue, frustration, or task saturation) and prescribes corrective actions to mitigate these risks. These actions may include recommending workload redistribution, prompting re-prioritization of tasks, or issuing alerts to address critical mission elements.

The VA may reinforce correct actions and communications in real-time while addressing performance deficiencies dynamically. For example, the VA may deliver positive affirmations for accurate communications or issue corrective guidance when a critical task is delayed or overlooked. Additionally, the VA may dynamically prioritize tasks and redirect operator attention to ensure alignment with mission-critical objectives. This proactive, adaptive support allows operators to excel even under the cognitive demands of highly complex operational scenarios.

The application of the VA extends beyond military environments. In emergency management, the VA may assist incident coordinators by monitoring sensor data, responder actions, and communication patterns to ensure effective and timely responses. In logistics operations, the VA may optimize transportation schedules, monitor vehicle and operator status, and dynamically adjust routing to address disruptions or inefficiencies. Across all use cases, the VA's prescriptive analytics ensure that users remain effective, responsive, and focused on achieving optimal outcomes.

The modular and scalable design of the VA (as well as any other aspect of tutor process 110) ensures its applicability across a range of platforms, including laptops, tablets, dedicated C2 consoles, and VR/XR environments. When integrated within a C2 system, the VA enhances decision-making capabilities and operational efficiency in military, commercial, and emergency response applications.

As a result, as discussed above, the VA for Live Command and Control Operations leverages advanced AI tools, prescriptive analytics, and dynamic feedback mechanisms to deliver transformative operational support. By proactively identifying and addressing performance risks, the VA enables operators to successfully manage the demands of multi-domain environments, ensuring mission success and enhanced human performance.

It will be appreciated after reading the present disclosure that more than one user/player may be included at the same time. For example, simulations and live operations may involve two or more “real life” users/players, each with their own client electronic devices, that may work together and otherwise interact with tutor process 110 simultaneously. As such, the discussion of a single user/player should be taken as example only and not to otherwise limit the scope of the present disclosure.

The terminology used herein is for the purpose of describing particular implementations only and is not intended to be limiting of the disclosure. As used herein, the singular forms “a”, “an” and “the” are intended to include the plural forms as well, including any steps performed by a/the computer/processor, unless the context clearly indicates otherwise. As used herein, the phrase “at least one of A, B, and C” should be construed to mean a logical (A OR B OR C), using a non-exclusive logical OR, and should not be construed to mean “at least one of A, at least one of B, and at least one of C.” As another example, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof. Example sizes/models/values/ranges can have been given, although examples are not limited to the same.

The terms (and those similar to) “coupled,” “attached,” “connected,” “adjoining,” “transmitting,” “receiving,” “connected,” “engaged,” “adjacent,” “next to,” “on top of,” “above,” “below,” “abutting,” and “disposed,” used herein is to refer to any type of relationship, direct or indirect, between the components in question, and is to apply to electrical, mechanical, fluid, optical, electromagnetic, electromechanical, or other connections. Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action is to occur, either in a direct or indirect manner. The term “set” does not necessarily exclude the empty set—in other words, in some circumstances a “set” may have zero elements. The term “non-empty set” may be used to indicate exclusion of the empty set—that is, a non-empty set must have one or more elements, but this term need not be specifically used. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

The corresponding structures, materials, acts, and equivalents (e.g., of all means or step plus function elements) that may be in the claims below are intended to include any structure, material, or act for performing the function in combination with other claimed elements as specifically claimed. While the disclosure describes structures corresponding to claimed elements, those elements do not necessarily invoke a means plus function interpretation unless they explicitly use the signifier “means for.” Unless otherwise indicated, recitations of ranges of values are merely intended to serve as a shorthand way of referring individually to each separate value falling within the range, and each separate value is hereby incorporated into the specification as if it were individually recited. While the drawings divide elements of the disclosure into different functional blocks or action blocks, these divisions are for illustration only. According to the principles of the present disclosure, functionality can be combined in other ways such that some or all functionality from multiple separately-depicted blocks can be implemented in a single functional block; similarly, functionality depicted in a single block may be separated into multiple blocks. Unless explicitly stated as mutually exclusive, features depicted in different drawings can be combined consistent with the principles of the present disclosure.

The description of the present disclosure has been presented for purposes of illustration and description but is not intended to be exhaustive or limited to the disclosure in the form disclosed. After reading the present disclosure, many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated. The features of any dependent claim may be combined with the features of any of the independent claims or other dependent claims. It is contemplated that any of the blocks of any of the flowcharts may be combined with any other blocks of any other flowcharts, especially where a flowchart shares at least one identical or similar block.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A computer-implemented method comprising:
receiving, by a computing device, input data from a user participating in a live operation;
receiving input data from the live operation;
analyzing the input data from the user participating in the live operation and the input data from the live operation; and
providing feedback to the user participating in the live operation based upon, at least in part, analyzing the input data from the user participating in the live operation and the input data from the live operation.

2. The computer-implemented method of claim 1, wherein the input data from the user participating in the live operation includes at least one of user biometrics and user performance data, and wherein the input data from the live operation includes live state data.

3. The computer-implemented method of claim 1 further comprising predicting performance of the user in the live scenario to generate a predicted performance of the user.

4. The computer-implemented method of claim 3, wherein predicting performance of the user in the live operation to generate the predicted performance of the user includes processing, using a trained predictive model, at least one of input data from the user participating in a past simulation scenario, input data from the user participating in a past live operation, the input data from the user participating in the live operation and the input data from the live operation processed using feature engineering data.

5. The computer-implemented method of claim 1, wherein providing feedback to the user participating in the live operation includes triggering an intervention event in the live operation based upon, at least in part the input data from the user participating in the live operation and the input data from the live operation.

6. The computer-implemented method of claim 5 further comprising matching one of a predicted performance of the user, the input data from the user participating in the live operation, and the input data from the live operation to a rule of a plurality of rules.

7. The computer-implemented method of claim 5, wherein triggering the intervention event includes providing at least one of a visual cue, an audio cue, a virtual cue, and a virtual intervention.

8. A computer program product residing on a computer readable storage medium having a plurality of instructions stored thereon which, when executed across one or more processors, causes at least a portion of the one or more processors to perform operations comprising:
receiving input data from a user participating in a live simulation scenario;
receiving input data from the live operation;
analyzing the input data from the user participating in the live operation and the input data from the live operation; and
providing feedback to the user participating in the live operation based upon, at least in part, analyzing the input data from the user participating in the live operation and the input data from the live operation.

9. The computer program product of claim 8, wherein the input data from the user participating in the live operation includes at least one of user biometrics and user performance data, and wherein the input data from the live operation includes live state data.

10. The computer program product of claim 8, wherein the operations further comprise predicting performance of the user in the live operation to generate a predicted performance of the user.

11. The computer program product of claim 10, wherein predicting performance of the user in the live operation to generate the predicted performance of the user includes processing, using a trained predictive model, at least one of input data from the user participating in a past simulation scenario, input data from the user participating in a past live operation, the input data from the user participating in the live operation and the input data from the live operation processed using feature engineering data.

12. The computer program product of claim 8, wherein providing feedback to the user participating in the live operation includes triggering an intervention event in the live operation based upon, at least in part the input data from the user participating in the live operation and the input data from the live operation.

13. The computer program product of claim 12, wherein the operations further comprise matching one of a predicted performance of the user, the input data from the user participating in the live operation, and the input data from the live operation to a rule of a plurality of rules.

14. The computer program product of claim 12, wherein triggering the intervention event includes providing at least one of a visual cue, an audio cue, a virtual cue, and a virtual intervention.

15. A computing system including one or more processors and one or more memories configured to perform operations comprising:
receiving input data from a user participating in a live simulation scenario;
receiving input data from the live operation;
analyzing the input data from the user participating in the live operation and the input data from the live operation; and
providing feedback to the user participating in the live operation based upon, at least in part, analyzing the input data from the user participating in the live operation and the input data from the live operation.

16. The computing system of claim 15, wherein the input data from the user participating in the live operation includes at least one of user biometrics and user performance data, and wherein the input data from the live operation includes live state data.

17. The computing system of claim 15, wherein the operations further comprise predicting performance of the user in the live operation to generate a predicted performance of the user.

18. The computing system of claim 17, wherein predicting performance of the user in the live operation to generate the predicted performance of the user includes processing, using a trained predictive model, at least one of input data from the user participating in a past simulation scenario, the input data from the user participating in the input data from the user participating in a past live operation, and the input data from the live operation processed using feature engineering data.

19. The computing system of claim 15, wherein providing feedback to the user participating in the live operation includes triggering an intervention event in the live operation based upon, at least in part the input data from the user participating in the live operation and the input data from the live operation.

20. The computing system of claim 19, wherein the operations further comprise matching one of a predicted performance of the user, the input data from the user participating in the live operation, and the input data from the live operation to a rule of a plurality of rules.
